(19) United States
(12) Patent Application Publication
(10) Pub. No.: US 2016/0351472 A1
(43) Pub. Date: Dec. 1, 2016

(54) INTEGRATED CIRCUIT DEVICE AND METHOD OF MANUFACTURING THE SAME

(71) Applicants: MYEONG-SOON PARK, GOYANG-SI (KR); HYUN-SOO CHUNG, HWASEONG-SI (KR); CHAN-HO LEE, GWANGMYEONG-SI (KR)

(72) Inventors: MYEONG-SOON PARK, GOYANG-SI (KR); HYUN-SOO CHUNG, HWASEONG-SI (KR); CHAN-HO LEE, GWANGMYEONG-SI (KR)

(21) Appl. No.: 15/053,410

(22) Filed: Feb. 25, 2016

(30) Foreign Application Priority Data
May 28, 2015 (KR) 10-2015-0075371

(51) Int. Cl. H01L 23/48; H01L 23/00; H01L 23/532; H01L 25/065

(52) U.S. Cl. CPC H01L 23/481; H01L 25/0657; H01L 24/16; H01L 24/08; H01L 23/53238; H01L 23/53266; H01L 2225/06541; H01L 2225/06513; H01L 2224/0401; H01L 2224/05025; H01L 2224/16146; H01L 2924/14; H01L 2224/05017

(57) ABSTRACT

An integrated circuit device is provided as follows. A connection terminal is disposed on a first surface of a semiconductor structure. A conductive pad is disposed on a second surface, opposite to the first surface, of the semiconductor structure. A through-substrate-via (TSV) structure penetrates through the semiconductor structure. An end portion of the TSV structure extends beyond the second surface of the semiconductor structure. The conductive pad surrounds the end portion of the TSV structure. The connection terminal is electrically connected to the conductive pad through the TSV structure

### CROSS-REFERENCE TO RELATED APPLICATION

This application claims priority under 35 U.S.C. §119 to Korean Patent Application No. 10-2015-0075371, filed on May 28, 2015 in the Korean Intellectual Property Office, the disclosure of which is incorporated by reference herein in its entirety.

### TECHNICAL FIELD

The present inventive concept relates to an integrated circuit device and a method of manufacturing the integrated circuit device.

### DISCUSSION OF RELATED ART

Semiconductor dies are vertically stacked to form a three-dimensional (3D) package to increase storage capacity. In the 3D package, each semiconductor dies are electrically connected to each other using various electrical connection structures.

### SUMMARY

According to an exemplary embodiment of the present inventive concept, an integrated circuit device is provided as follows. A connection terminal is disposed on a first surface of a semiconductor structure. A conductive pad is disposed on a second surface, opposite to the first surface, of the semiconductor structure. A through-substrate-via (TSV) structure penetrates through the semiconductor structure. An end portion of the TSV structure extends beyond the second surface of the semiconductor structure. The conductive pad surrounds the end portion of the TSV structure. The connection terminal is electrically connected to the conductive pad through the electrical connection structure.

According to an exemplary embodiment of the present inventive concept, an integrated circuit device is provided as follows. A through-substrate-via (TSV) structure penetrates through a semiconductor structure. An insulating layer is disposed on the semiconductor structure. The insulation layer has a recess space exposing an end portion of the TSV structure. A conductive pad fills the recess space and is connected to the end portion of the TSV structure.

According to an exemplary embodiment of the present inventive concept, a method of manufacturing an integrated circuit device is provided as follows. A via hole is formed in a semiconductor structure having a first surface and a second surface. The via hole penetrates the semiconductor structure and extends from the first surface to the second surface. A preliminary through-substrate-via (TSV) structure is formed in the via hole so that a first end portion of the preliminary TSV structure protrudes beyond the second surface of the semiconductor structure. An insulating layer is formed on the second surface and the first end portion of the preliminary TSV structure. A recess space is formed by partially removing the insulating layer so that a second end portion of the preliminary TSV structure is exposed. A TSV structure is formed by removing partially the second end portion of the preliminary TSV structure through the recess space. A conductive pad is formed so that the conductive pad fills the recess space and covers an end portion of the TSV structure, wherein the end portion of the TSV structure is exposed by the recess space. A connection terminal is formed on the first surface of the semiconductor structure. The connection terminal is electrically connected to the conductive pad through the TSV structure.

According to an exemplary embodiment of the present inventive concept, a semiconductor device is provided.

A first integrated circuit device has a first electrical connection structure and a connection terminal which is electrically connected to the first electrical connection structure.

A second integrated circuit device is vertically stacked on the first integrated circuit device.

The connection terminal electrically connects the first electrical connection structure to the second integrated circuit device.

The first integrated circuit device further comprises a first semiconductor structure and a conductive pad. The first semiconductor structure has a first surface and a second surface opposite to the first surface. The connection terminal is disposed on the first surface. The conductive pad is disposed on the second surface. The first electrical connection structure penetrates through the first semiconductor structure. An end portion of the first electrical connection structure extends beyond the second surface of the first semiconductor structure. The conductive pad surrounds the end portion of the first electrical connection structure. The connection terminal is electrically connected to the conductive pad through the first electrical connection structure.

### BRIEF DESCRIPTION OF DRAWINGS

These and other features of the inventive concept will become more apparent by describing in detail exemplary embodiments thereof with reference to the accompanying drawings of which:

FIG. 1 is a cross-sectional view of an integrated circuit device according to an exemplary embodiment of the present inventive concept;

FIG. 2 is a cross-sectional view of an integrated circuit device according to an exemplary embodiment of the present inventive concept;

FIG. 3 is a cross-sectional view of an integrated circuit device according to an exemplary embodiment of the present inventive concept;

FIG. 4 is a cross-sectional view of an integrated circuit device according to an exemplary embodiment of the present inventive concept;

FIG. 5 is a cross-sectional view of an integrated circuit device according to an exemplary embodiment of the present inventive concept;

FIG. 6 is a cross-sectional view of an integrated circuit device according to an exemplary embodiment of the present inventive concept;

FIG. 7 is a cross-sectional view of an integrated circuit device according to an exemplary embodiment of the present inventive concept;

FIG. 8 is a cross-sectional view of an integrated circuit device according to an exemplary embodiment of the present inventive concept;

FIG. 9 is a cross-sectional view of a semiconductor package according to an exemplary embodiment of the present inventive concept;

FIGS. 10A to 10R are cross-sectional views illustrating a method of manufacturing an integrated circuit device, according to an exemplary embodiment of the present inventive concept;

FIG. 11 is a cross-sectional view showing a semiconductor package according to an exemplary embodiment of the present inventive concept;

FIG. 12 is a cross-sectional view of a semiconductor package according to an exemplary embodiment of the present inventive concept;

FIG. 13 is a cross-sectional view of a semiconductor package according to an exemplary embodiment of the present inventive concept;

FIG. 14 is a cross-sectional view of a semiconductor package according to an exemplary embodiment of the present inventive concept;

FIG. 15 is a plan view showing an integrated circuit device according to an exemplary embodiment of the present inventive concept; and

FIG. 16 is a diagram showing an integrated circuit device according to an exemplary embodiment.

Although corresponding plan views and/or perspective views of some cross-sectional view(s) need not be shown, the cross-sectional view(s) of device structures illustrated herein provide support for a plurality of device structures that extend along two different directions as would be illustrated in a plan view, and/or in three different directions as would be illustrated in a perspective view. The two different directions may or need not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

### DETAILED DESCRIPTION OF EXEMPLARY EMBODIMENTS

Exemplary embodiments of the inventive concept will be described below in detail with reference to the accompanying drawings. However, the inventive concept may be embodied in different forms and should not be construed as limited to the embodiments set forth herein. In the drawings, the thickness of layers and regions may be exaggerated for clarity. It will also be understood that when an element is referred to as being “on” another element or substrate, it may be directly on the other element or substrate, or intervening layers may also be present. It will also be understood that when an element is referred to as being “coupled to” or “connected to” another element, it may be directly coupled to or connected to the other element, or intervening elements may also be present. Like reference numerals may refer to the like elements throughout the specification and drawings.

Hereinafter, the exemplary embodiments will be described below with reference to accompanying drawings.

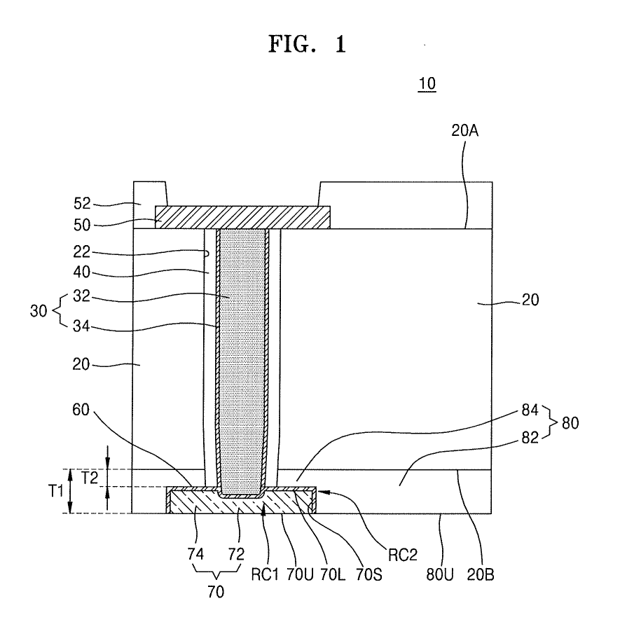

FIG. 1 is a cross-sectional view of an integrated circuit device 10 according to an exemplary embodiment.

Referring to FIG. 1, the integrated circuit device 10 includes a semiconductor structure 20, and a through-substrate-via (TSV) structure 30 penetrating the semiconductor structure 20 through a via hole 22 formed in the semiconductor structure 20.

The TSV structure 30 includes a conductive plug 32 penetrating through the semiconductor structure 20, and a conductive barrier layer 34 surrounding the conductive plug 32. The conductive barrier layer 34 may have a cylindrical shape surrounding the conductive plug 32.

In an exemplary embodiment, the conductive plug 32 of the TSV structure 30 may include copper (Cu) or tungsten (W). For example, the conductive plug 32 may be formed of Cu, CuSn, CuMg, CuNi, CuZn, CuPd, CuAu, CuRe, CuW, W, or a W alloy, but is not limited thereto.

In an exemplary embodiment, the conductive barrier layer 34 may include Ti, TiN, Ta, TaN, Ru, Co, Mn, WN, Ni, or NiB.

In an exemplary embodiment, the conductive barrier layer 34 and the conductive plug 32 may be formed by performing a physical vapour deposition (PVD) process or a chemical vapour deposition (CVD) process, but is not limited thereto.

In an exemplary embodiment, the semiconductor structure 20 may be formed of a semiconductor substrate, e.g., a silicon substrate, and the TSV structure 30 may have side walls surrounded by the semiconductor substrate.

In an exemplary embodiment, the semiconductor structure 20 may include a semiconductor substrate and an insulating interlayer covered on the semiconductor substrate. In addition, the TSV structure 30 may penetrate through the semiconductor substrate and the insulating interlayer.

In an exemplary embodiment, if the semiconductor structure 20 includes the semiconductor substrate and the insulating interlayer covered on the semiconductor substrate, the TSV structure 30 need not penetrate through the insulating interlayer while penetrating through the semiconductor substrate.

In an exemplary embodiment, the semiconductor structure 20 may include a semiconductor substrate, an insulating interlayer covered on the semiconductor substrate, and an intermetal insulating layer covered on the insulating interlayer. In addition, the TSV structure 30 may penetrate through the semiconductor substrate, the insulating interlayer, and the intermetal insulating layer.

In an exemplary embodiment, a via insulating layer 40 is disposed between the semiconductor structure 20 and the TSV structure 30. The via insulating layer 40 may have a cylindrical shape surrounding the TSV structure 30, and may include an oxide layer, a nitride layer, a carbide layer, a polymer, or a combination thereof.

A first conductive layer 50 connected to an end of the TSV structure 30 is formed on a first surface 20A of the semiconductor structure 20, and a passivation layer 52 covering a part on the first surface 20A of the semiconductor structure 20, on which the first conductive layer 50 is not formed, and at least a part on the first conductive layer 50 may be formed. A second conductive layer 60 connected to the other end of the TSV structure 30 and a conductive pad 70 connected to the other end of the TSV structure 30 via the second conductive layer 60 are formed on a second surface 20B of the semiconductor structure 20. An upper insulating layer 80 surrounding the conductive pad 70 is formed on the second surface 20B of the semiconductor structure 20.

In an exemplary embodiment, the first conductive layer 50 may be formed of Al, and the passivation layer 52 may be formed of an insulating material such as polyimide, silicon nitride, or silicon oxynitride.

In an exemplary embodiment, the second conductive layer 60 forms an under bump metallization (UBM) layer, and may include layers of various compositions according to a material forming the conductive pad 70. In an exemplary embodiment, the second conductive layer 60 may be formed of Ti, Cu, Ni, Au, NiV, NiP, TiNi, TiW, TaN, Al, Pd, CuCr, or a combination thereof. For example, the second conductive layer 60 may have a stack structure including Cr/Cu/Au, a stack structure including Cr/CrCu/Cu, TiWCu compound, a stack structure including TiWCu/Cu, a stack structure including Ni/Cu, a stack structure including NiV/Cu, a stack structure including Ti/Ni, a stack structure including Ti/NiP, TiWNiV compound, a stack structure including Al/Ni/Au, a stack structure including Al/NiP/Au, a stack structure including Ti/TiNi/CuNi compound, a stack structure including Ti/Ni/Pd, a stack structure including Ni/Pd/Au, or a stack structure including NiP/Pd/Au.

The conductive pad 70 has a bottom surface 70L connected to the other end of the TSV structure 30 via the second conductive layer 60, an upper surface 70U that is opposite to the bottom surface 70L, and side walls 70S connecting the bottom surface 70L and the upper surface 70U. The conductive pad 70 may be formed of Ni, Cu, Al, Au, or a combination thereof, but is not limited thereto.

The conductive pad 70 includes a first portion 72 that vertically overlaps with the TSV structure 30 and a second portion 74 that does not vertically overlap with the TSV structure 30. A first recess space RC1 is formed in the first portion 72 of the conductive pad 70, receiving the TSV structure 30 in the first recess space RC1. The second conductive layer 60 is interposed between the first portion 72 and the TSV structure 30. The other end of the TSV structure 30 has a rounded shape, and the second conductive layer 60 conformally covers the other end of the TSV structure 30. A part of the conductive pad 70 is connected to the TSV structure 30 through the second conductive layer 60 which is interposed between the conductive pad 70 and the TSV structure 30, (e.g., the first portion 72). The rounded-shape end of the TSV structure 30 is connected to the conductive pad 70 through the second conductive layer 60. Accordingly, the rounded-shape end of the TSV structure 30 may increase contact area between the TSV structure 30 and the conductive pad 70, and adhesion strength between the conductive pad 70 and the TSV structure 30 increases such that detachment or delamination of the conductive pad 70 from the TSV structure 30 may be prevented.

In FIG. 1, the conductive barrier layer 34 need not be formed on an end portion of the TSV structure 30. The end portion of the TSV structure 30 faces the conductive pad 70. For example, the end portion of the TSV structure 30 is disposed in the first recess space RC1, and the end portion is an end portion of the conductive plug 32. Accordingly, the first portion 72 of the conductive pad 70 and the conductive plug 32 of the TSV structure 30 may be electrically connected to each other via the second conductive layer 60 interposed between the TSV structure 30 and the conductive pad 70 in the first recess space RC1. However, the present inventive concept is not limited thereto. For example, unlike in FIG. 1, the conductive barrier layer 34 covers the conductive plug 32 in the first recess space RC1.

The upper insulating layer 80 surrounds the bottom surface 70L and the side walls 70S of the conductive pad 70 on the second surface 20B of the semiconductor structure 20. In an exemplary embodiment, the upper insulating layer 80 includes a first portion 82 which does not vertically overlap the conductive pad 70, and a second portion 84 vertically overlapping with the conductive pad 70 and formed integrally with the first portion 82. The second portion 84 is disposed between the conductive pad 70 and the semiconductor structure 20.

In an exemplary embodiment, the second portion 84 of the upper insulating layer 80 surrounds side walls of the via insulating layer 40 between the bottom surface 70L of the conductive pad 70 and the second surface 20B of the semiconductor structure 20. However, the present inventive concept is not limited thereto. For example, the via insulating layer 40 is not formed on the side walls of the TSV structure 30. In this case, the second portion 84 of the upper insulating layer 80 surrounds the side walls of the TSV structure 30.

A first thickness T1 and a second thickness T2 of the upper insulating layer 80 may be set appropriately according to a width of the TSV structure 30, a height of the semiconductor structure 20, and a thickness of the passivation layer 52. In an exemplary embodiment, the first portion 82 of the upper insulating layer 80 has the first thickness T1 and the second portion 84 of the upper insulating layer 80 has the second thickness T2 that is less than the first thickness T1. The second thickness T2 of the second portion 84 in the upper insulating layer 80 may be about 20% to about 80% of the first thickness T1. For example, the second portion 84 of the upper insulating layer 80 may have the second thickness T2 that is about 50% of the first thickness T1. In an exemplary embodiment, the first thickness T1 may be about 1 μm to about 10 μm, but is not limited thereto. In addition, the second thickness T2 may be about 0.2 μm to about 8 but is not limited thereto.

In an exemplary embodiment, the first thickness T1 of the upper insulating layer 80 and the thickness of the passivation layer 52 may be set such that warpage of the semiconductor structure 20 may be prevented. For example, the first thickness T1 of the upper insulating layer 80 may be about 50% to about 150% of the thickness of the passivation layer 52, but the present inventive concept is not limited thereto. For example, the first thickness T1 of the upper insulating layer 80 may be substantially equal to the thickness of the passivation layer 52. In this case, the intrinsic stress (a compression or tensile stress) of the passivation layer 52 applied to the semiconductor structure 20 may be cancelled by the intrinsic stress of the upper insulating layer 80. Accordingly, warpage of the semiconductor structure 20 due to the intrinsic stresses and the coefficient of thermal expansion mismatch among the passivation layer 52, the semiconductor structure 20 and the upper insulating layer 80 may be prevented.

In FIG. 1, a second recess space RC2 is formed in the first portion 82 of the upper insulating layer 80 due to a difference between the first thickness T1 and the second thickness T2 of the first portion 82 and the second portion 82 in the upper insulating layer 80. The second recess space RC2 exposes the other end of the TSV structure 30. In addition, the second conductive layer 60 is disposed on an internal wall of the second recess space RC2, and the conductive pad 70 is located on the second conductive layer 60 to fill the second recess space RC2. Since the conductive pad 70 is disposed to fill the second recess space RC2, the bottom surface 70L and the side walls 70S of the conductive pad 70 are respectively connected to the first portion 82 and the second portion 84 of the upper insulating layer 80. The bottom surface 70L and the side walls 70S of the conductive pad 70 may respectively face the first portion 82 and the second portion 84 of the upper insulating layer 80, with the second conductive layer 60 disposed therebetween. Accordingly, a contact area between the conductive pad 70 and the upper insulating layer 80 may be increased so that the conductive pad 70 and the upper insulating layer 80 may form a firm bonding structure. Thus, the detachment or delamination of the conductive pad 70 from the upper insulating layer 80 may be prevented.

In FIG. 1, an upper surface 80U of the first portion 82 of the upper insulating layer 80 may be located at the same level as the upper surface 70U of the conductive pad 70. Here, the upper surface 80U of the first portion 82 of the upper insulating layer 80 does not directly contact the second surface 20B of the semiconductor structure 20, but is an opposite surface to a bottom surface 80L of the upper insulating layer 80, which directly contacts the second surface 20B of the semiconductor structure 20. Since the second portion 84 of the upper insulating layer 80 is located at the same level as the upper surface 70U of the conductive pad 70, an underfill member (not shown) may be formed without generating a void when the integrated circuit device 10 is attached to another semiconductor chip (not shown) or a package substrate (not shown).

In an exemplary embodiment, the upper insulating layer 80 may include a photosensitive organic insulating material. For example, the upper insulating layer 80 may include photosensitive polyimide (PSPI), benzocyclobuten (BCB), polybenzoxazole (PBO), fullerene derivative, etc., but is not limited thereto.

In this case, the upper insulating layer 80 may be, using a partial-dose photolithography process, patterned to form a recess in which the conductive pad 70 is formed. For example, an exposure amount of the photolithography may be controlled such that a part of the upper insulating layer 80 is removed to form the second recess space RC2 in the upper insulating layer 80. The exposure amount may be less than an exposure amount necessary to fully develop the upper insulating layer 80 having the first thickness T1. For example, the exposure amount of the photolithography may be half the exposure amount necessary to fully develop the upper insulating layer 80. The second portion 84 may be formed integrally with the first portion 82. The partial-dose photolithography may produce the second portion 84 having the second thickness T2.

In the integrated circuit device 10, since the contact area between the conductive pad 70 and the TSV structure 30 and/or the upper insulating layer 80 increases, the detachment or delamination of the conductive pad 70 from the TSV structure 30 and/or the upper insulating layer 80 may be prevented. Also, since the upper surface 70U of the conductive pad 70 is located at the same level as the upper surface 80U of the upper insulating layer 80, the underfill member may be formed without generating a void when attaching the conductive pad on another semiconductor chip or a package substrate. In addition, the intrinsic stress (the compression or tensile stress) of the passivation layer 52 may be cancelled by the intrinsic stress of the upper insulating layer 80 so that warpage of the semiconductor structure 20 due to the compression or tensile stress of the passivation layer 52 may be prevented. Therefore, the integrated circuit device 10 may be reliable.

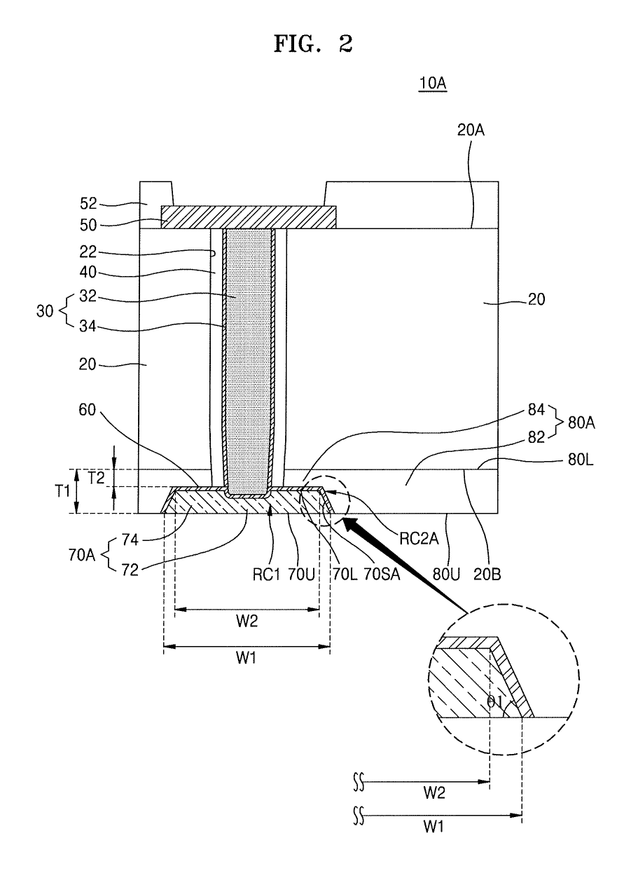

FIG. 2 is a cross-sectional view of an integrated circuit device 10A according to an exemplary embodiment. The integrated circuit device 10A of FIG. 2 is similar to the integrated circuit device 10 of FIG. 1 except for a shape of a conductive pad 70A. The difference of the conductive pad 70A will be described below. In FIG. 2, like reference numerals denote like elements, and detailed descriptions of the like elements are omitted here.

Referring to FIG. 2, a side wall 70SA of the conductive pad 70A is inclined with respect to the upper surface 70U of the conductive pad 70A by a first inclination angle θ1. For example, the first inclination angle θ1 may be about 30° to about 90°, but is not limited thereto. As shown in FIG. 2, a side wall of a second recess space RC2A of the upper insulating layer 80A is inclined by a predetermined angle (e.g., an angle similar to the first inclination angle θ1), the second conductive layer 60 is conformally formed on an inner wall of the second recess space RC2A, and the conductive pad 70A fills the second recess space RC2A on the second conductive layer 60. However, the present inventive concept is not limited thereto. As a thickness of the second conductive layer 60 formed on the side wall of the second recess space RC2A varies in a vertical direction, the side wall 70SA of the conductive pad 70A filling the second recess space RC2A is inclined with respect to the upper surface 80U of the upper insulating layer 80A by the first inclination angle θ1.

In an exemplary embodiment, the upper surface 70U of the conductive pad 70A has a first width W1 along a horizontal direction, and the bottom surface 70L of the conductive pad 70A has a second width W2 that is less than the first width W1 along the horizontal direction. Since the first width W1 of the upper surface 70U of the conductive pad 70A is greater than the second width W2 of the bottom surface 70L, or due to the inclined side wall 70SA of the conductive pad 70A, the contact area between the upper insulating layer 80A and the conductive pad 70A is increased such that the detachment or delamination of the conductive pad 70A may be prevented.

In an exemplary embodiment, the inclined side wall may be formed during the partial-dose photolithography process for forming the second recess space RC2A. The partial-dose photolithography process for forming the second recess space RC2A may include a process of applying a photosensitive organic insulating material, a half-dose exposure process, a post exposure baking (PEB) process, a developing process, and a hard baking process (or curing process) that are sequentially performed. The inclined side wall of the second recess space RC2A may be formed in the developing process. For example, the uppermost portion of the side wall of the second recess space RC2A may be exposed to a developing solution for a long time in the developing process after the PEB process, and accordingly, an etching amount from the upper side wall of the second recess space RC2A may be greater than that from a lower side wall of the second recess space RC2A in the developing process. Accordingly, the side wall of the second recess space RC2A may be inclined at a predetermined angle.

In an exemplary embodiment, the inclined side wall of the second recess space RC2A may be formed in the hard baking process. The hard baking process may be a process of thermally treating the photosensitive organic insulating material layer that has undergone the developing process at a hard baking temperature that is slightly higher than a glass transition temperature (Tg) of the photosensitive organic insulating material layer. A profile of the side wall of the photosensitive organic insulating layer after the hard baking process may vary depending on physical properties of the photosensitive organic insulating material layer such as a thermal flow property or the glass transition temperature of the photosensitive organic insulating material layer, the hard baking temperature, the hard baking time duration, and cooling speed. For example, even if the side wall of the second recess space RC2A is formed substantially vertical after the developing process, the side wall of the second recess space RC2A may be inclined at a predetermined angle after the hard baking process.

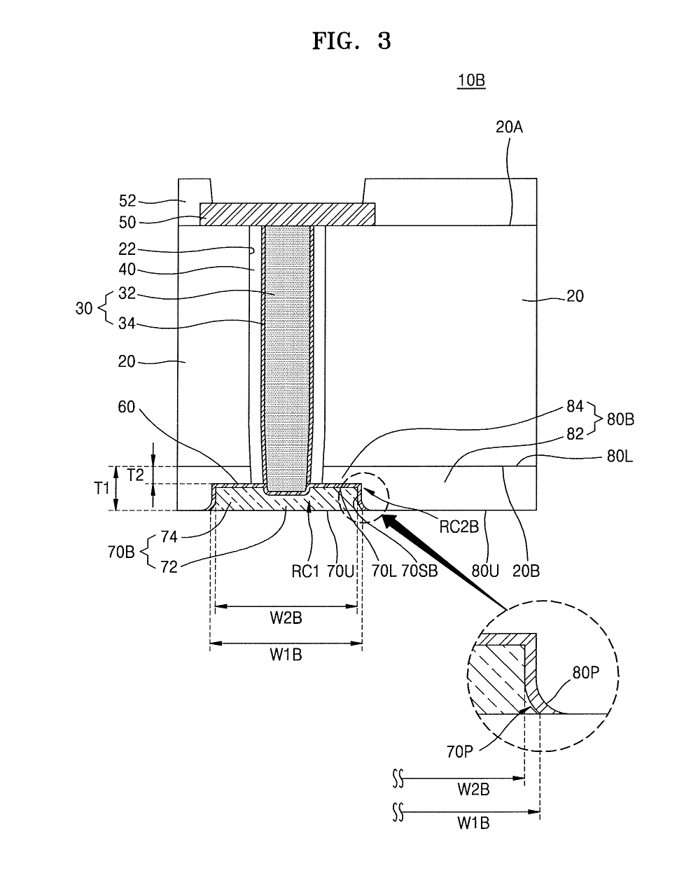

FIG. 3 is a cross-sectional view of an integrated circuit device 10B according to an exemplary embodiment. The integrated circuit device 10B of FIG. 3 is similar to the integrated circuit device 10 of FIG. 1 except for a shape of a conductive pad 70B. The difference of the conductive pad 70B will be described below. In FIG. 3, like reference numerals as those of FIGS. 1 and 2 denote like elements, and detailed descriptions of the like elements are omitted here.

Referring to FIG. 3, a side wall of a second recess space RC2B of an upper insulating layer 80B has a rounded portion 80P adjacent to the upper surface 80U of the upper insulating layer 80B. The second conductive layer 60 is conformally formed on an inner wall of the second recess space RC2B of the upper insulating layer 80B, and the conductive pad 70B fills the second recess space RC2B on the second conductive layer 60. A protrusion 70P is formed on the conductive pad 70B that faces the rounded portion 80P formed on the side wall of the second recess space RC2B while the second conductive layer 60 is interposed between the second recess space RC2B and the conductive pad 70B.

A width of the uppermost portion of the second recess space RC2B (that is, a width of the second recess space RC2B located at the same level as the upper surface 80U of the upper insulating layer 80B) is greater than that of a bottom portion of the second recess space RC2B due to the rounded portion 80P formed on the side wall of the second recess space RC2B. Therefore, a first width W1B of the upper surface 70U of the conductive pad 70B along the horizontal direction is greater than a second width W2B of the bottom surface 70L along the horizontal direction.

Since the first width W1B of the upper surface 70U of the conductive pad 70B is greater than the second width W2B of the bottom surface 70L (or due to the protrusion 70P of the conductive pad 70B), the contact area between the upper insulating layer 80B and the conductive pad 70B is increased such that the detachment and delamination of the conductive pad 70B may be prevented.

In an exemplary embodiment, the rounded portion 80P may be formed in the partial-dose photolithography process for forming the second recess space RC2B. In an exemplary embodiment, the rounded portion 80P may be formed on a side wall of the second recess space RC2B in the developing process. For example, the uppermost portion of the side wall of the second recess space RC2B may be exposed to the developing solution for a long time during the developing process, and accordingly, an etching amount from the upper side wall of the second recess space RC2B may be greater than that from the lower side wall of the second recess space RC2B. Accordingly, the rounded portion 80P may be formed on the side wall of the second recess space RC2B.

In an exemplary embodiment, the rounded portion 80P is formed on the side wall of the second recess space RC2B during the hard baking process. The hard baking process may be a process of thermally treating the photosensitive organic insulating material layer that has undergone the developing process at a hard baking temperature that is slightly higher than a glass transition temperature (Tg) of the photosensitive organic insulating material layer. A profile of the side wall of the photosensitive organic insulating layer after the hard baking process may vary depending on physical properties of the photosensitive organic insulating material layer such as a thermal flow property or the glass transition temperature of the photosensitive organic insulating material layer, the hard baking temperature, the hard baking time duration, and cooling speed. For example, even if the side wall of the second recess space RC2B is formed substantially vertical after the developing process, the rounded portion 80P may be formed on the side wall of the second recess space RC2B after the hard baking process.

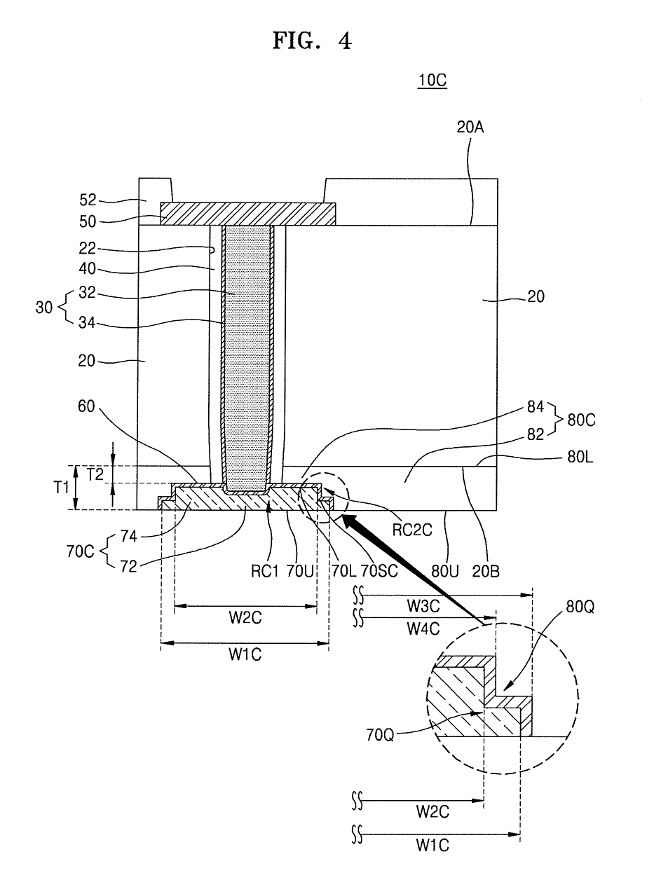

FIG. 4 is a cross-sectional view of an integrated circuit device 10C according to an exemplary embodiment. The integrated circuit device 10C of FIG. 4 is similar to the integrated circuit device 10 of FIG. 1 except for a shape of a conductive pad 70C. The difference will be described below. In FIG. 4, like reference numerals as those of FIGS. 1 to 3 denote the same elements, and thus, detailed descriptions thereof will be omitted.

Referring to FIG. 4, a side wall of a second recess space RC2C of an upper insulating layer 80C has a stepped portion 80Q. The second conductive layer 60 is formed conformally on an inner wall of the second recess space RC2C, and the conductive pad 70C fills the second recess space RC2C on the second conductive layer 60. A stepped portion 70Q is formed on a part of the conductive pad 70B, which faces the stepped portion 80Q formed on the side wall of the second recess space RC2C, as the second conductive layer 60 is interposed between the second recess space RC2C and the conductive pad 70C.

Due to the stepped portion 80Q formed on the side wall of the second recess space RC2C, a third width W3C that is a width of the uppermost portion of the second recess space RC2C, that is, the width of the second recess space RC2C located at the same level as the upper surface 80U of the upper insulating layer 80B, is greater than a fourth width W4C that is a width of the bottom portion of the second recess space RC2C. Therefore, a first width W1C of the upper surface 70U of the conductive pad 70C along a horizontal direction is greater than a second width W2C of the bottom surface 70L of the conductive pad 70C along the horizontal direction. Therefore, the contact area between the upper insulating layer 80C and the conductive pad 70C is increased such that the detachment or delamination of the conductive pad 70C may be prevented.

In an exemplary embodiment, the stepped portion 80Q may be formed during a partial-dose photolithography process for forming the second recess space RC2C. In an exemplary embodiment, the partial-dose photolithography process may include a first partial-dose photolithography process and a second partial-dose photolithography process that are sequentially performed. For example, the upper portion of the second recess space RC2C having the third width W3C may be formed in the first partial-dose photolithography process, and after that, the lower portion of the second recess space RC2C having the fourth width W4C may be formed in the second partial-dose photolithography process. In FIG. 4, the stepped portion 80Q is formed by performing the first and second partial-dose photolithography processes sequentially, but the present inventive concept is not limited thereto. For example, three or more partial-dose photolithography processes may be sequentially performed to form parts of the second recess space RC2C, which have different widths.

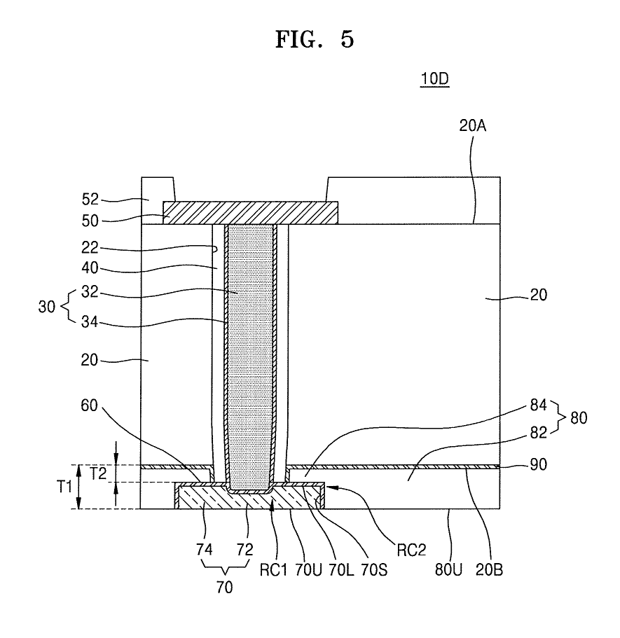

FIG. 5 is a cross-sectional view of an integrated circuit device 10D according to an exemplary embodiment. The integrated circuit device 10D is similar to the integrated circuit device 10 of FIG. 1 except for an adhesion layer 90. The difference will be described below. In FIG. 5, like reference numerals as those of FIGS. 1 to 4 denote the same elements, and descriptions of the like elements will be omitted here.

Referring to FIG. 5, the adhesion layer 90 is disposed between the semiconductor structure 20 and the upper insulating layer 80 and between the upper insulating layer 80 and the via insulating layer 40. The adhesion layer 90 is disposed to surround the side wall of the TSV structure 30 between the bottom surface 70L of the conductive pad 70 and the second surface 20B of the semiconductor structure 20. The adhesion layer 90 may increase adhesive strength between the semiconductor structure 20 and the upper insulating layer 80, or may function as an intermediate layer formed on a rough surface of the semiconductor structure 20 to provide a flat surface.

In an exemplary embodiment, the adhesion layer 90 may include silicon nitride, silicon oxynitride, silicon oxide, or a combination thereof, but the present inventive concept is not limited thereto. In addition, the adhesion layer 90 may be formed by a Physical Vapour Deposition (PVD) process or a Chemical Vapour Deposition (CVD) process, but the present inventive concept is not limited thereto.

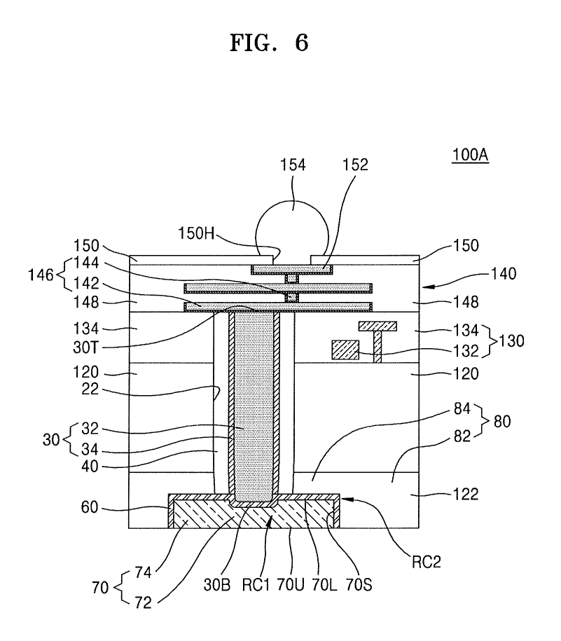

FIG. 6 is a cross-sectional view of an integrated circuit device 100A according to an exemplary embodiment. In FIG. 6, like reference numerals as those of FIGS. 1 to 5 denote the same elements, and detailed descriptions thereof are omitted here.

The integrated circuit device 100A includes a substrate 120, a front-end-of-line (FEOL) structure 130, and a back-end-of-line (BEOL) structure 140. The TSV structure 30 is formed in a via hole 22 penetrating through the substrate 120 and the FEOL structure 130. The via insulating layer 40 is disposed between the substrate 120 and the TSV structure 130, and between the FEOL structure 130 and the TSV structure 30.

The TSV structure 30 includes the conductive plug 32 penetrating through the substrate 120 and the FEOL structure 130, and the conductive barrier layer 34 surrounding the conductive plug 32.

The substrate 120 may be a semiconductor wafer. In an exemplary embodiment, the substrate 120 includes silicon (Si). In an exemplary embodiment, the substrate 120 may include a semiconductor element such as germanium (Ge), or a compound semiconductor such as silicon carbide (SiC), gallium arsenide (GaAs), indium arsenide (InAs), and indium phosphide (InP). In an exemplary embodiment, the substrate 120 may have a silicon on insulator (SOI) structure. For example, the substrate 120 may include a buried oxide layer (BOX) layer. In an exemplary embodiment, the substrate 120 may include a conductive region, e.g., a well doped with impurities or a structure doped with impurities. In addition, the substrate 120 may have various device isolation structure such as a shallow trench isolation (STI) structure.

The FEOL structure 130 includes a plurality of individual devices 132 of various kinds, and an insulating interlayer 134. The plurality of individual devices 132 may include various microelectronic devices, e.g., a metal-oxide-semiconductor field effect transistor (MOSFET), a system large scale integration (LSI), an image sensor such as a CMOS imaging sensor (CIS), a micro-electro-mechanical system (MEMS), an active device, and a passive device. The plurality of individual devices 132 may be electrically connected to the conductive region of the substrate 120. Also, the plurality of individual devices 132 may be electrically isolated from other neighbouring individual devices by the insulating interlayer 134.

The BEOL structure 140 includes a multi-layered wiring structure 146 including a plurality of metal wiring layers 142 and a plurality of contact plugs 144. The multi-layered wiring structure 146 may be connected to the TSV structure 30. In an exemplary embodiment, the microelectronic devices of the FEOL structure 130 may be electrically connected to TSV structure 30 through the BEOL structure 140.

In an exemplary embodiment, the BEOL structure 140 may further include other multi-layered wiring structures, each including a plurality of metal wiring layers and a plurality of contact plugs, on other regions of the substrate 120. The BEOL structure 140 may include a plurality of wiring structures for connecting the individual devices included in the FEOL structure 130 to other wires. The multi-layered wiring structure 146 and the other wiring structures included in the BEOL structure 140 may be insulated from each other by an intermetal insulating layer 148. In an exemplary embodiment, the BEOL structure 140 may further include a seal ring (not shown) for protecting the plurality of wiring structures and other structured under the wiring structures against external shock or moisture.

An upper surface 30T of the TSV structure 30 extending through the substrate 120 and the FEOL structure 130 may be electrically connected to the metal wiring layer 142 of the multi-layered wiring structure 146 included in the BEOL structure 140.

The passivation layer 150 is formed on the intermetal insulating layer 148. The passivation layer 150 may include a silicon oxide layer, a silicon nitride layer, a polymer, or a combination thereof. A hole 150H exposing a bonding pad 152 connected to the multi-layered wiring structure 146 is formed in the passivation layer 150. The bonding pad 152 may be electrically connected to an upper connection terminal 154 via the hole 150H. The upper connection terminal 154 need not be limited to an example shown in FIG. 6, but may be formed as a conductive pad, a solder ball, a solder bump, or a redistribution conductive layer. In an exemplary embodiment, the upper connection terminal 154 may be omitted.

The upper insulating layer 80 is formed on a bottom surface of the substrate 120, and includes a second recess space RC2 exposing a bottom surface 30B of the TSV structure 30. The second conductive layer 60 connected to the bottom surface 30B of the TSV structure 30 is formed on an inner wall of the second recess space RC2, and the conductive pad 70 filling the second recess space RC2 is formed on the second conductive layer 60.

Processes of forming the BEOL structure 140, the upper connection terminal 154, the upper insulating layer 80, the second conductive layer 60, and the conductive pad 70 is formed after forming the TSV structure 30.

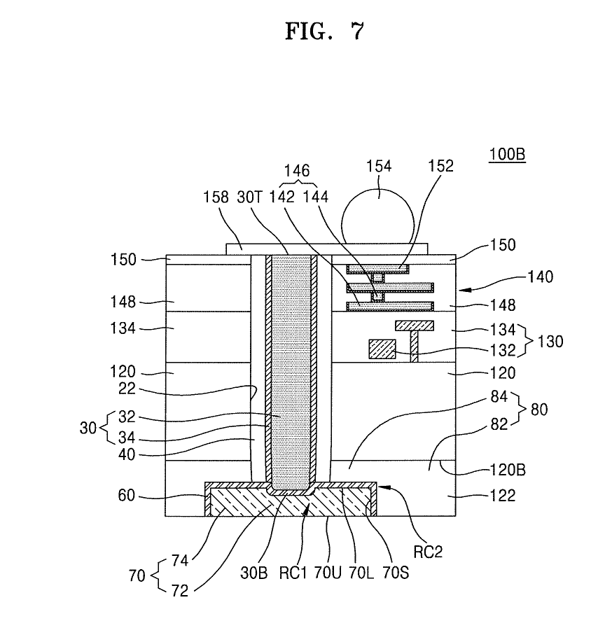

FIG. 7 is a cross-sectional view of an integrated circuit device 100B according to an exemplary embodiment. In FIG. 7, like reference numerals as those of FIGS. 1 to 6 denote the same elements, and detailed descriptions thereof are omitted.

In the integrated circuit device 100B, the TSV structure 30 may be formed after forming the FEOL structure 130 and the BEOL structure 140. Therefore, the TSV structure 30 penetrates through the substrate 120, the insulating interlayer 134 of the FEOL structure 130, and the intermetal insulating layer 148 of the BEOL structure 140. The conductive barrier layer 34 of the TSV structure 30 includes a first outer wall portion surrounded by the substrate 120, a second outer wall portion surrounded by the insulating interlayer 134, and a third outer wall portion surrounded by the intermetal insulating layer 148.

An upper wire 158 extends between the TSV structure 30 and the upper connection terminal 154 on the BEOL structure 140 to electrically connect the TSV structure 30 and the upper connection terminal 154 to each other. The TSV structure 30 may be electrically connected to the upper wire 158 after penetrating through the passivation layer 150, and may be electrically connected to the upper connection terminal 154 via the upper wire 158. The upper connection terminal 154 is not limited to the example shown in FIG. 7, but may be formed as a conductive pad, a solder ball, a solder bump, or a redistribution conductive layer. In an exemplary embodiment, the upper connection terminal 154 may be omitted.

The upper insulating layer 80 is formed on the bottom surface of the substrate 120, and includes the second recess space RC2 exposing the bottom surface 30B of the TSV structure 30. The second conductive layer 60 connected to the bottom surface 30B of the TSV structure 30 is formed on the inner wall of the second recess space RC2, and the conductive pad 70 filling the second recess space RC2 is formed on the second conductive layer 60.

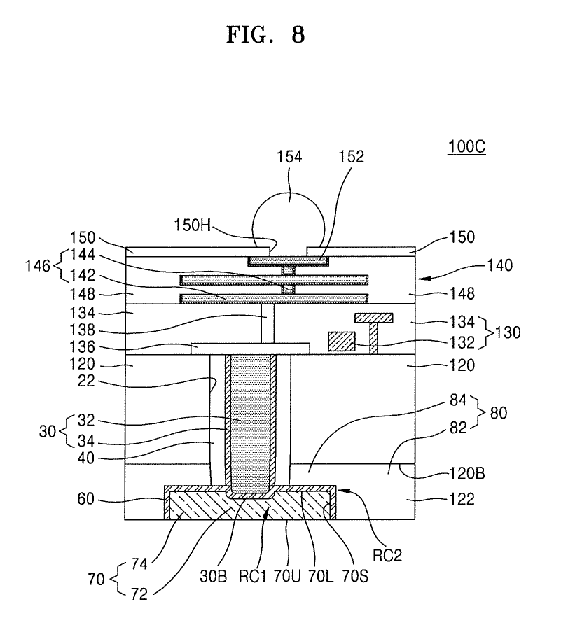

FIG. 8 is a cross-sectional view of an integrated circuit device 100C according to an exemplary embodiment. In FIG. 8, like reference numerals as those of FIGS. 1 to 7 denote the same elements, and detailed descriptions thereof are omitted here.

In the integrated circuit device 100C, the TSV structure 30 extends to penetrate through the substrate 120. After forming the TSV structure 30, the FEOL structure 130 and the BEOL structure 140 are formed on the TSV structure 30 and the substrate 120. The TSV structure 30 may be electrically connected to the multi-layered wiring structure 146 included in the BEOL structure 140 via connecting wires 136 and 138 included in the FEOL structure 130.

The upper insulating layer 80 is formed on the bottom surface of the substrate 120, and includes the second recess space RC2 exposing the bottom surface 30B of the TSV structure 30. The second conductive layer 60 connected to the bottom surface 30B of the TSV structure 30 is formed on the inner wall of the second recess space RC2, and the conductive pad 70 filling the second recess space RC2 is formed on the second conductive layer 60.

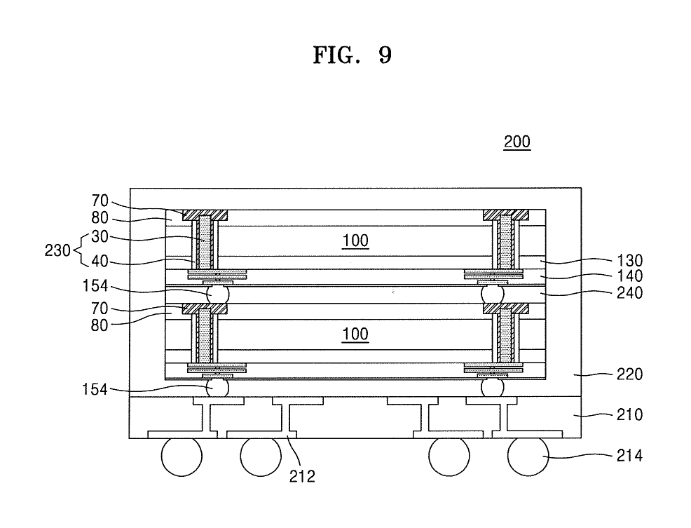

FIG. 9 is a cross-sectional view of a semiconductor package 200 according to an exemplary embodiment. In FIG. 9, like reference numerals as those of FIGS. 1 to 8 denote the same elements, and detailed descriptions thereof are omitted here.

Referring to FIG. 9, the semiconductor package 200 includes a package substrate 210, and at least one integrated circuit device 100 mounted on the package substrate 210.

In an exemplary embodiment, the package substrate 210 may be a printed circuit board (PCB) including a wiring structure 212 formed therein.

In FIG. 9, the semiconductor package 200 having two integrated circuit devices 100 is shown as an example, but the present inventive concept is not limited thereto. For example, various numbers of the integrated circuit devices 100 may be mounted on the package substrate 210 in a vertical direction or a horizontal direction. In FIG. 9, some elements of the integrated circuit device 100 are omitted for convenience of description. The integrated circuit device 100 may have a structure according to an exemplary embodiment. In each integrated circuit device 100, the TSV structure 30 and the via insulating layer 40 surrounding the TSV structure 30 may form a TSV unit 230. In FIG. 9, the BEOL structure 140 is formed, but the present inventive concept is not limited thereto. For example, unlike the example shown in FIG. 9, the BEOL structure 140 may be omitted from an integrated circuit device.

The package substrate 210 includes a plurality of connection terminals 214 connecting to internal wiring structure 212 for electrically connecting to outside. In an exemplary embodiment, the plurality of connection terminals 214 may be solder balls, but are not limited thereto.

The package substrate 210 and the integrated circuit device 100, or two adjacent integrated circuit devices 100 may be electrically connected to each other via the TSV structure 30, the upper connection terminal 154 and the conductive pad 70 formed in the integrated circuit device 100. The second conductive layer 60 of FIGS. 1-8 are omitted for the convenience of description.

In FIG. 9, two integrated circuit devices 100 are mounted on the package substrate 210 in the vertical direction to be electrically connected to each other in the semiconductor package 200. Here, the conductive pad 70 formed in the integrated circuit device 100 at a lower side is in contact with the upper connection terminal 154 formed in the integrated circuit device 100 at an upper side, and an underfill member 240 is further formed in a space between the integrated circuit device 100 at the upper side and the integrated circuit device 100 at the lower side. In an exemplary embodiment, the underfill member 240 may include a non-conductive film (NCF), a non-conductive polymer (NCP), a die attach film (DAF), a capillary underfill (CUF), or a molded underfill (MUF), but the present inventive concept is not limited thereto. The underfill member 240 is formed to surround the upper connection terminal 154 between the upper insulating layer 80 and the conductive pad 70 of the lower integrated circuit device 100 and the BEOL structure 140 of the upper integrated circuit device 100. Since the upper surface of the upper insulating layer 80 is located at the same level as the upper surface of the conductive pad 70, the underfill member 240 is formed without generating a void during the process of forming the underfill member 240.

The semiconductor package 200 may include a molding layer 220 for molding the at least one integrated circuit device 100. In an exemplary embodiment, the molding layer 220 may be formed of polymer. For example, the molding layer 220 may be formed of an epoxy molding compound (EMC).

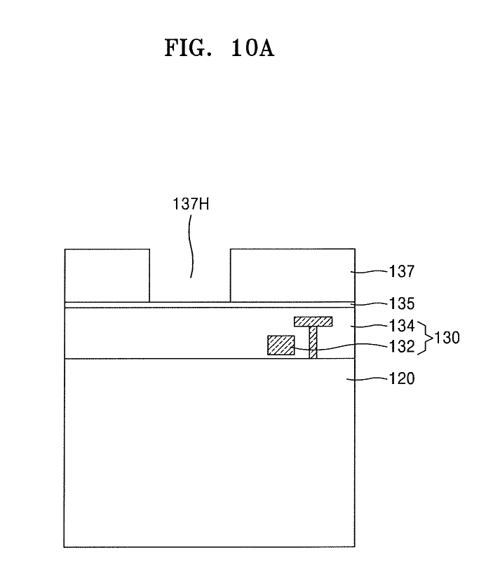

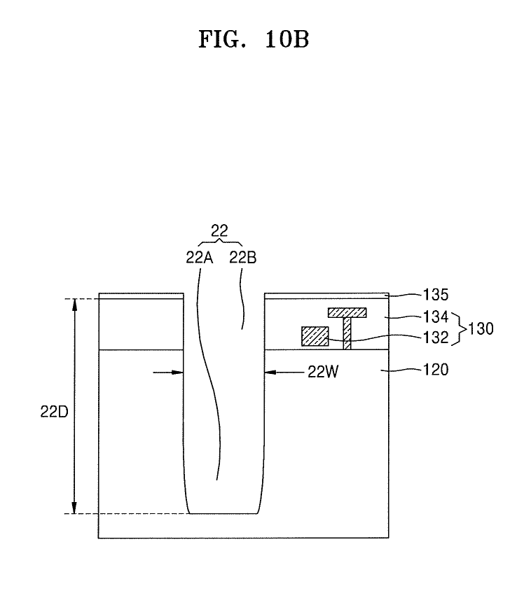

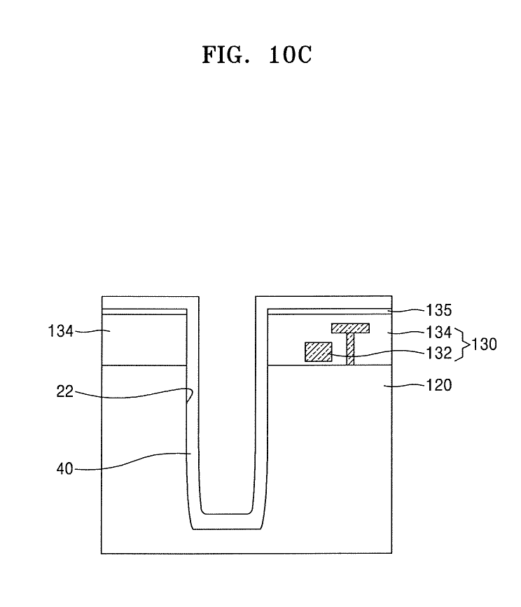

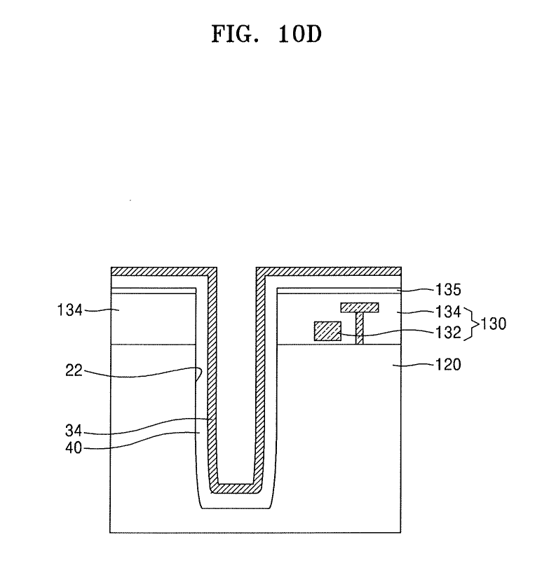

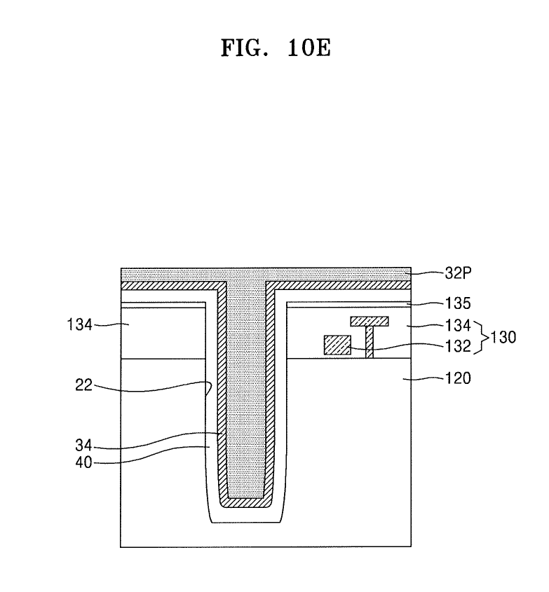

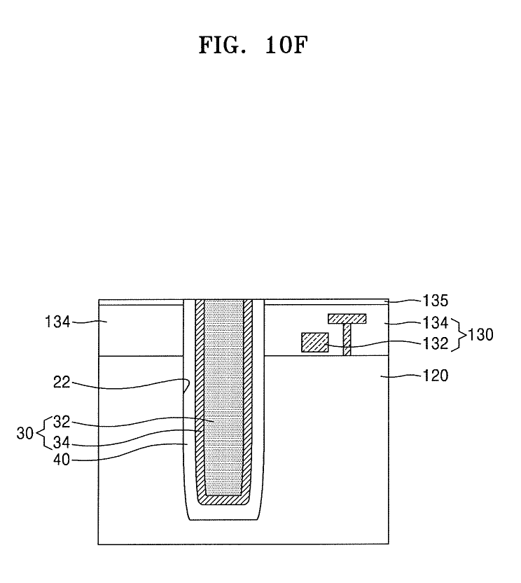

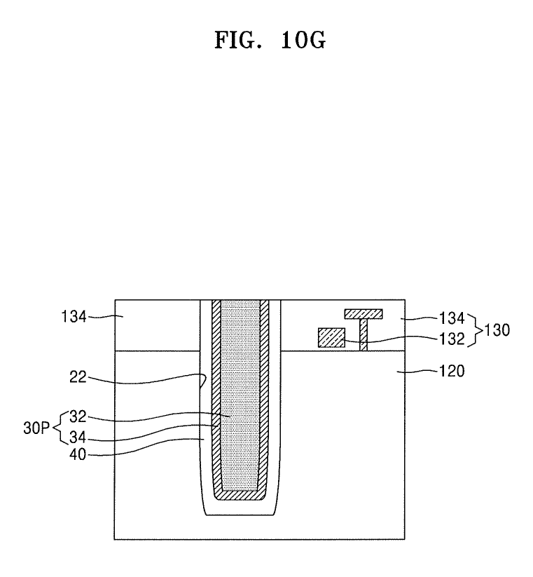

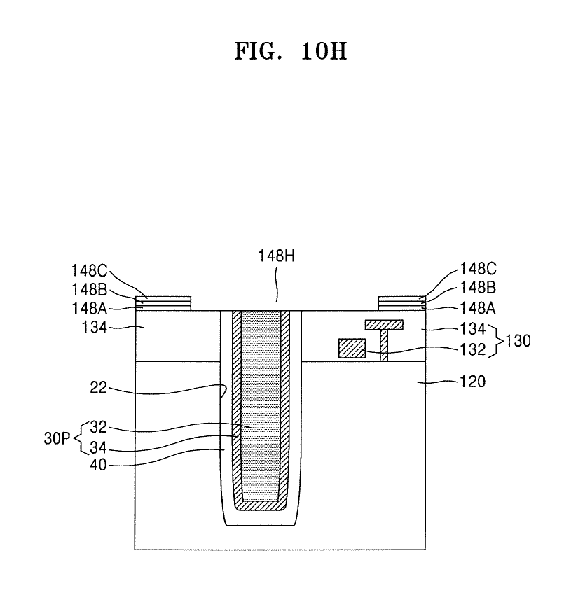

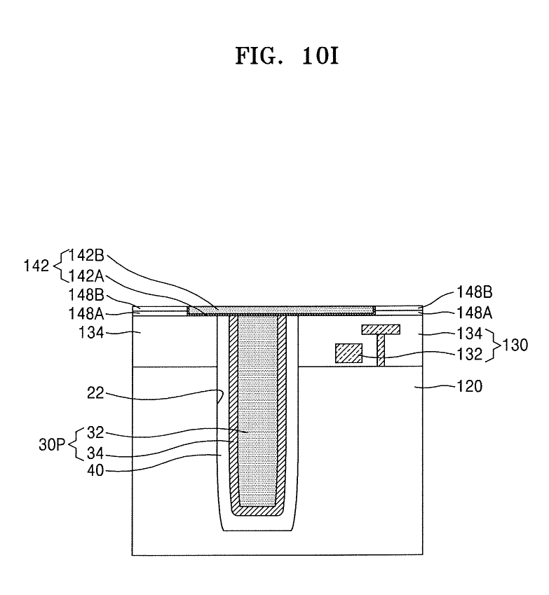

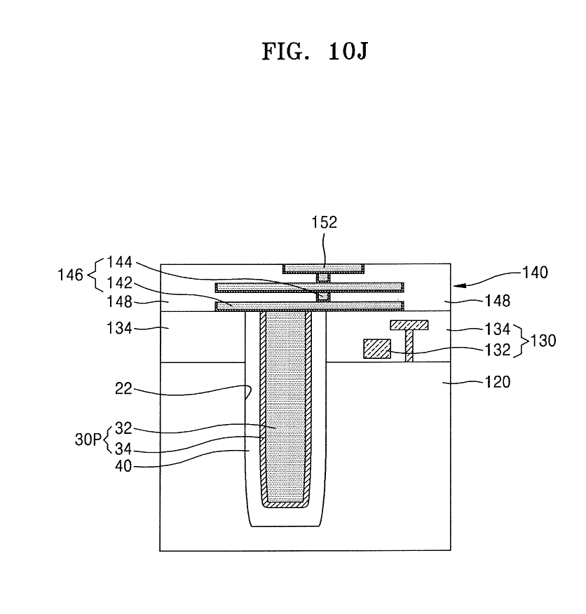

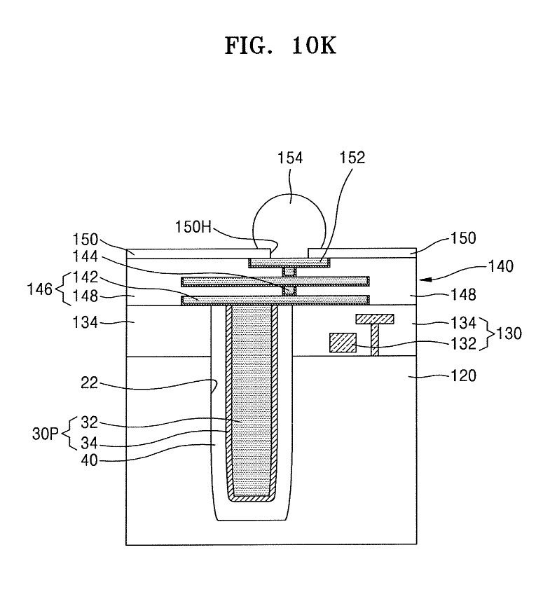

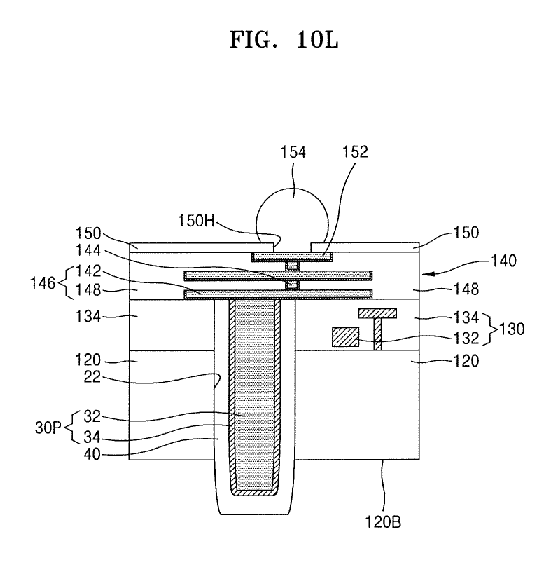

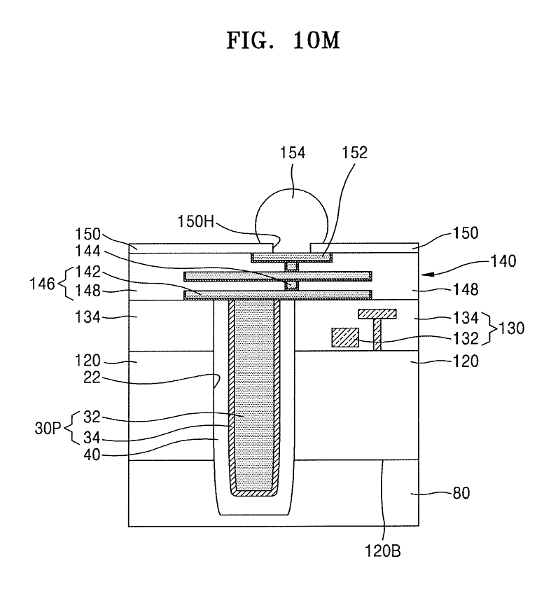

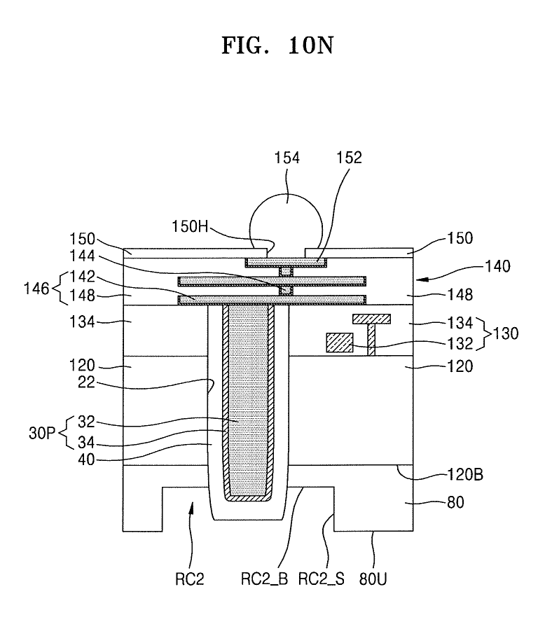

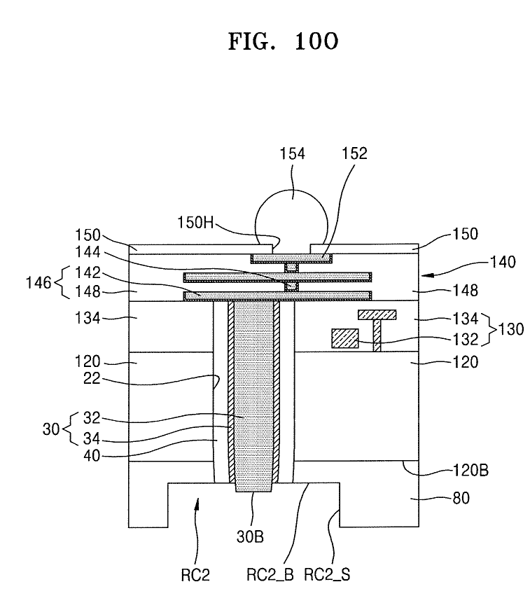

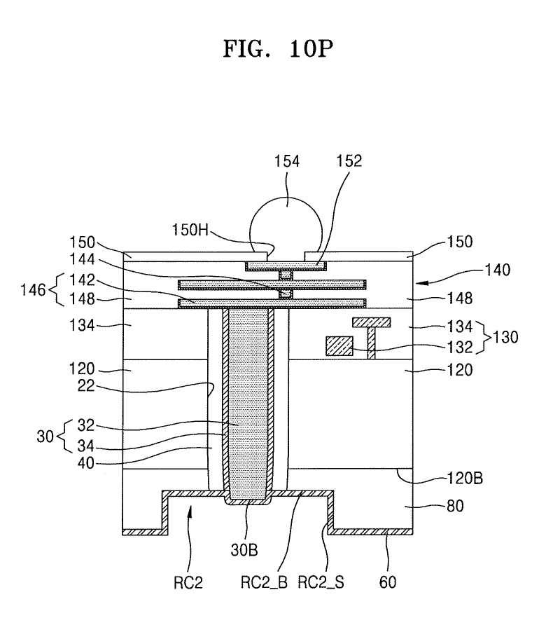

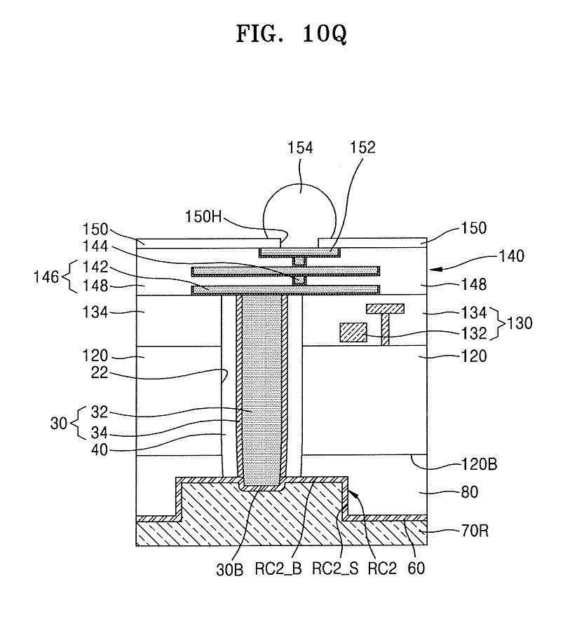

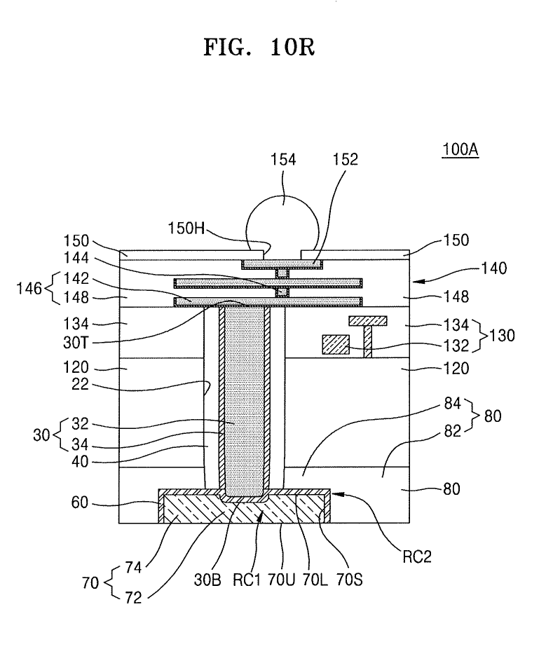

FIGS. 10A to 10R are cross-sectional views illustrating a method of manufacturing the integrated circuit device 100A of FIG. 6 according to an exemplary embodiment. In FIGS. 10A to 10R, like reference numerals as those of FIGS. 1 to 6 denote the same elements, and detailed descriptions thereof are omitted here.

Referring to FIG. 10A, the FEOL structure 130 is formed on the substrate 120, a first polish stop layer 135 is formed on the FEOL structure 130, and a mask pattern 137 is formed on the first polish stop layer 135. The mask pattern 137 includes a hole 137H that partially exposes an upper surface of the first polish stop layer 135.

In an exemplary embodiment, the first polish stop layer 135 may be formed of a silicon nitride layer or a silicon oxynitride layer. The first polish stop layer 135 may be formed to a thickness of about 200 Å to about 1000 Å. The first polish stop layer 135 may be formed by a CVD process.

The mask pattern 137 may include a photoresist layer.

Referring to FIG. 10B, the first polish stop layer 135 and the insulating interlayer 134 are etched by using the mask pattern 137 (see FIG. 10A) as an etching mask, and the substrate 120 is etched to form the via hole 22. The via hole 22 includes a first hole 22A formed in the substrate 120 to a predetermined depth, and a second hole 22B penetrating through the insulating interlayer 134 so that the first hole 22A and the second hole 22B are connected to each other.

An anisotropic etching process may be used to form the via hole 22. In an exemplary embodiment, the via hole 22 may be formed to a width 22W of about 10 μm or less in the substrate 120. In an exemplary embodiment, the via hole 22 may be formed to a depth 22D of about 50 μM to about 100 μM from an upper surface of the insulating interlayer 134. However, the width 22W and the depth 22D of the via hole 22 are not limited to the above examples, but may vary according to an exemplary embodiment. The substrate 120 is exposed through the first hole 22A of the via hole 22, and the insulating interlayer 134 is exposed through the second hole 22B of the via hole 22. In an exemplary embodiment, the via hole 22 may be formed by using a laser drilling technology.

After forming the via hole 22, the mask pattern 137 is removed to expose an upper surface of the first polish stop layer 135.

Referring to FIG. 10C, the via insulating layer 40 covering an inner side wall and a bottom surface of the via hole 22 are formed.

The via insulating layer 40 is formed to cover the surface of the substrate 120 and the surface of the insulating interlayer 134, which are exposed in the via hole 22, and the surface of the first polish stop layer 135.

Referring to FIG. 10D, the conductive barrier layer 34 is formed on the via insulating layer 40 in and out of the via hole 22.

In an exemplary embodiment, the PVD process or the CVD process may be used to form the conductive barrier layer 34. The conductive barrier layer 34 may be formed as a single layer including a kind of material or a multiple layer including at least two kinds of materials. In an exemplary embodiment, the conductive barrier layer 34 may include W, WN, WC, Ti, TiN, Ta, TaN, Ru, Co, Mn, WN, Ni, or NiB. For example, the conductive barrier layer 34 may have a stack structure including a TaN layer having a thickness of about 50 Å to about 200 Å and a Ta layer having a thickness of about 1000 Å to about 3000 Å.

Referring to FIG. 10E, a conductive layer 32P filling the remaining space in the via hole 22 is formed on the conductive barrier layer 34.

The process for forming the conductive layer 32P may be performed after the process of forming the conductive barrier layer 34 described above with reference to FIG. 10D without breaking a vacuum atmosphere in which the conductive barrier layer 34 has been formed. In an exemplary embodiment, a pressure when the conductive barrier layer 34 is formed and a pressure when the conductive layer 32P is formed may be different from each other.

The conductive layer 32P covers the conductive barrier layer 34 inside and outside the via hole 22.

In an exemplary embodiment, an electroplating process may be used to form the conductive layer 32P. For example, a metal seed layer (not shown) is formed on a surface of the conductive barrier layer 34, and a metal layer is grown from the metal seed layer by the electroplating process to form the conductive layer 32P filling the via hole 22 on the conductive barrier layer 34. The metal seed layer may be formed of Cu, Cu alloy, Co, Ni, Ru, Co/Cu, or Ru/Cu. The metal seed layer may be formed by a PVD process. The conductive layer 32P may include Cu or W. For example, the conductive layer 32P may be formed of Cu, CuSn, CuMg, CuNi, CuZn, CuPd, CuAu, CuRe, CuW, W, or W alloy, but the present inventive concept is not limited thereto. The electroplating process may be performed at a temperature of about 10° C. to about 65° C. For example, the electroplating process may be performed at a room temperature. In an exemplary embodiment, the conductive layer 32P may be annealed at a temperature of about 150° C. to about 450° C.

Referring to FIG. 10F, the conductive layer 32P of FIG. 10E may be polished by a chemical mechanical polishing (CMP) process by using the first polish stop layer 135 as a stopper until the first polish stop layer 135 is exposed. In an exemplary embodiment, the exposed first polish stop layer may be further polished after the exposed first polish stop layer is exposed.

As a result, the via insulating layer 40, the conductive barrier layer 34, and the conductive layer 32P located at outside the via hole 22 may be removed, and the conductive plug 32 is formed from the conductive layer 32P on the conductive barrier layer 34 in the via hole 22. The combined structure of the conductive plug 32 and the conductive barrier layer 34 may be referred to as a preliminary TSV structure. In an exemplary embodiment, the combined structure of the conductive plug 32 and the conductive barrier layer 34 of FIG. 10F may be referred to as a preliminary TSV structure.

In an exemplary embodiment, the resulting structure of FIG. 10 may be subject to an annealing process. In this case, metal particles included in the conductive plug 32 are grown due to the annealing process, and thus, a surface roughness of the conductive plug 32 may increase. In an exemplary embodiment, the annealing process may be performed at a temperature of about 400° C. to about 500° C.

Referring to FIG. 10G, the first polish stop layer 135 may be removed through a CMP process so that the upper surface of the insulating interlayer 134 in the FEOL structure 130 may be exposed to outside. In the CMP process, the uneven surface of the conductive plug 32 due to the metal particles and the annealing process may be planarized by the CMP process. In an exemplary embodiment, the annealing process may be performed at a temperature of about 400° C. to about 500° C.

In the via hole 22, a preliminary TSV structure 30P including the conductive plug 32 and the conductive barrier layer 34 surrounding the conductive plug 32 may remain.

Referring to FIG. 10H, the preliminary TSV structure 30P of FIG. 10G is washed, and after that, a second polish stop layer, an insulating layer, and a third polish stop layer are sequentially formed on the insulating interlayer 134, and are patterned to form a second polish stop layer pattern 148A, an insulating layer pattern 148B, a third polish stop layer pattern 148C, and a metal wiring hole 148H exposing the upper surface of the TSV structure 30 and peripheral portions of the TSV structure 30 at an inlet side of the via hole 22.

The second polish stop layer pattern 148A may be used as an etch stopper when the metal wiring hole 14811 is formed.

The preliminary TSV structure 30P, the via insulating layer 40, and the insulating interlayer 134 are partially exposed through the metal wiring hole 148H. In an exemplary embodiment, the metal wiring hole 148H may be formed to only expose the upper surface of the preliminary TSV structure 30P.

In an exemplary embodiment, the insulating layer pattern 148B may be formed of tetra-ethyl-ortho-silicate (TEOS). The second polish stop layer pattern 148A and the third polish stop layer pattern 148C may be formed of a silicon nitride layer or a silicon oxynitride layer, respectively. Each of the second polish stop layer pattern 148A, the insulating layer pattern 148B, and the third polish stop layer pattern 148C may have various thickness in an exemplary embodiment.

Referring to FIG. 10I, the metal wiring layer 142 may be formed in the metal wiring hole 148H.

The metal wiring layer 142 includes a wiring barrier layer 142A and a wiring metal layer 142B which are sequentially stacked.

In an exemplary embodiment, to form the metal wiring layer 142, a first layer for forming the wiring barrier layer 142A and a second layer for forming the wiring metal layer 142B may be sequentially formed in the metal wiring hole 148H (see FIG. 10H) and on the third polish stop layer pattern 148C (see FIG. 10H), and then, the resulting structure including the first and second layers may be polished by a CMP process using the third polish stop layer pattern 148C as a stopper. In the CMP process, the third polish stop layer pattern 148C may be removed so that the upper surface of the insulating layer pattern 148B may be exposed. As a result, the metal wiring layer 142 including the wiring barrier layer 142A and the wiring metal layer 142B remains in the metal wiring hole 148H after the CMP process.

In an exemplary embodiment, the wiring barrier layer 142A may include Ti, TiN, Ta, or TaN. In an exemplary embodiment, the PVD process may be performed to form the wiring barrier layer 142A. The wiring barrier layer 142A may have a thickness of about 1000 Å to about 1500 Å.

In an exemplary embodiment, the wiring metal layer 142B may include Cu. To form the wiring metal layer 142B, a Cu seed layer is formed on the surface of the wiring barrier layer 142A, and after that, a Cu layer is grown on the Cu seed layer through an electroplating process, and a resulting structure including the Cu layer is annealed.

Referring to FIG. 10J, a contact plug 144 is formed on the metal wiring layer 142 by using a process that is similar to the process of forming the metal wiring layer 142 described above with reference to FIGS. 10H and 10I. After that, the process of forming the metal wiring layer 142 described with reference to FIGS. 10H and 10I and the process of forming the contact plug 144 are alternately performed a plurality of times to form the multi-layered wiring structure 146 and the bonding pad 152. In the multi-layered wiring structure 146, each of the plurality of metal wiring layers 142 and each of the plurality of contact plugs 144 are alternately connected to each other. The bonding pad 152 is connected to the multi-layered wiring structure 146.

In FIG. 10J, the multi-layered wiring structure 146 includes two metal wiring layers 142 and two contact plugs 144, but the present inventive concept is not limited thereto. In addition, in the multi-layered wiring structure 146 of FIG. 10J, the connecting structure between the metal wiring layer 142 and the contact plug 144 is an example. The present inventive concept is not limited to the structure shown in FIG. 10J.

In an exemplary embodiment, the plurality of metal wiring layers 142 and the plurality of contact plugs 144 may each include W, Al, or Cu. In an exemplary embodiment, the plurality of metal wiring layers 142 and the plurality of contact plugs 144 may be formed of the same material as each other. In an exemplary embodiment, at least some of the plurality of metal wiring layers 142 and the plurality of contact plugs 144 may include different materials from each other.

In an exemplary embodiment, when the multi-layered wiring structure 146 is formed, other multi-layered wiring structures (not shown) including metal wiring layers and contact plugs that are formed simultaneously with at least some of the plurality of metal wiring layers 142 and the plurality of contact plugs 144 may be formed on other regions of the substrate 120. Then, the intermetal insulating layer 148 including the plurality of second polish stop layer patterns 148A and a plurality of insulating layer patterns 148B (see FIG. 10I) and the BEOL structure 140 including the plurality of multi-layered wiring structures having the portions insulated by the intermetal insulating layer 148 are obtained on the FEOL structure 130. The BEOL structure 140 may include a plurality of wiring structures for connecting the separate devices included in the FEOL structure 130 to other wires formed on the substrate 120. In an exemplary embodiment, the BEOL structure 140 may further include a seal ring for protecting the wiring structures and the other structures under the wiring structures against the external shock or moisture.

Referring to FIG. 10K, the passivation layer 150 including the hole 150H that exposes the bonding pad 152 is formed on the BEOL structure 140, and then, the upper connection terminal 154 connected to the bonding pad 152 via the hole 150H is formed on the passivation layer 150.

In an exemplary embodiment, the passivation layer 150 may include a silicon oxide layer, a silicon nitride layer, a polymer, or a combination thereof.

Referring to FIG. 10L, the substrate 120 is partially removed from the bottom surface thereof so that the preliminary TSV structure 30P surrounded by the via insulating layer 40 protrudes from the bottom surface 120B of the substrate 120.

Referring to FIG. 10M, the upper insulating layer 80 covering the bottom surface 120B of the substrate 120 is formed. The upper insulating layer 80 covers the via insulating layer 40 protruding from the bottom surface 120B of the substrate 120.

In an exemplary embodiment, the upper insulating layer 80 may be formed of a photosensitive organic insulating material by a spin coating process. For example, the upper insulating layer 80 may include photosensitive polyimide (PSPI), benzocyclobuten (BCB), polybenzoxazole (PBO), fullerene derivatives, etc., but is not limited thereto.

In an exemplary embodiment, the resulting structure including the upper insulating layer 80 may be annealed. As a result of the annealing process, an organic solvent remaining in the upper insulating layer 80 may be removed. In an exemplary embodiment, the annealing process may be performed at a temperature of about 90° C. to about 110° C.

In an exemplary embodiment, the upper insulating layer 80 is formed directly on the bottom surface 120B of the substrate 120 and the via insulating layer 40 in FIG. 10M. However, unlike the example illustrated in FIG. 10M, the adhesion layer 90 (see FIG. 5) may be formed to a predetermined thickness before forming the upper insulating layer 80, and the upper insulating layer 80 is formed on the adhesion layer 90. The adhesion layer 90 may be formed of, for example, silicon nitride, silicon oxide, silicon oxynitride, or polymer, by a CVD process.

Referring to FIG. 10N, the second recess space RC2 is formed in the upper insulating layer 80 to expose the via insulating layer 40.

In an exemplary embodiment, the process for forming the second recess space RC2 may be a partial-dose photolithography process. The partial-dose photolithography process may be a photolithography process using a an exposure amount with which the upper insulating layer 80 is only removed to a predetermined thickness and a partial thickness of the upper insulating layer 80 remains.

The partial-dose photolithography process may include a partial-dose exposure process, a post exposure baking (PEB) process, a developing process, and a hard baking process (or curing process) that are sequentially performed.

In the partial-dose exposure process, the upper insulating layer 80 may be exposed by using the partial-dose exposure amount so that the upper insulating layer 80 is partially removed to a predetermined thickness. In an exemplary embodiment, the partial-dose exposure amount (D₁₁₂) may be about 30% to about 70% of a reference exposure amount D₀, by which the entire thickness of the upper insulating layer 80 may be removed, but the present invention is not limited thereto. For example, the partial-dose exposure process may be performed on the upper insulating layer 80 by using the partial-dose exposure amount D₁₁₂ that is about 50% of the reference exposure amount D₀.

After the partial-dose exposure process, the PEB process may be performed. In the PEB process, an annealing process may be performed at a temperature of about 100° C. to about 120° C. to accelerate dispersion of the photosensitive agent contained in the photosensitive organic insulating material.

After the PEB process, the developing process may be performed. For example, in the developing process, a KOH or tetramethyl-ammonium-hydroxide (TMAH) aqueous solution may be used, but the present inventive concept is not limited thereto. In the developing process, the upper insulating layer 80 may be removed partially so that the via insulating layer 40 may be exposed.

After the developing process, the hard baking process may be performed. In the hard baking process, an annealing process may be performed at a temperature that is higher than a glass transition temperature Tg of the material included in the upper insulating layer 80. As a result of the hard baking process, the second recess space RC2 exposing the via insulating layer 40 may be formed in the upper insulating layer 80.

In FIG. 10N, the second recess space RC2 is shown to have a side wall RC2_S that is substantially perpendicular to the upper surface 80U of the upper insulating layer 80. However, the present inventive concept is not limited thereto. In an exemplary embodiment, a profile of the side wall of the photosensitive organic insulating layer after the hard baking process may vary depending on physical properties of the photosensitive organic insulating material such as a thermal flow property or the glass transition temperature of the photosensitive organic insulating material, the hard baking temperature, the hard baking time duration, and the cooling speed. For example, even when the side wall RC2_S of the second recess space RC2 is substantially perpendicular to the upper surface 80U after the developing process, the side wall of the second recess space RC2A (see FIG. 2) may be inclined by a predetermined angle after the hard baking process. In this case, the integrated circuit device 10A of FIG. 2 may be formed to have an inclined side wall.

On the other hand, even if the side wall of the second recess space RC2B is substantially perpendicular to the upper surface 80U after the developing process, the rounded portion 80P (see FIG. 3) may be formed on the side wall of the second recess space RC2B (see FIG. 3) after the hard baking process. In this case, the integrated circuit device 10B described above with reference to FIG. 3 may be formed to have a side wall having a rounded portion.

In addition, a first partial-dose patterning process and a second partial-dose patterning process may be performed sequentially so that the upper portion of the second recess space RC2C (see FIG. 4) having the third width W3C (see FIG. 4) may be formed in the first partial-dose photolithography process and the lower portion of the second recess space RC2C having the fourth width W4C (see FIG. 4) may be formed in the second partial-dose photolithography process. In this case, the stepped portion 80Q (see FIG. 4) is formed on the side wall of the second recess space RC2C, and the integrated circuit device 10C described above with reference to FIG. 4 is formed.

Referring to FIG. 10O, an etch-back process is performed on the resulting structure of FIG. 10N including the second recess space RC2 to a TSV structure 30. In the etch-back process, the via insulating layer 40 and the conductive barrier layer 34 exposed in the second recess space RC2 are removed from the preliminary TSV structure 30P and the conductive plug 32 is exposed through the second recess space RC2.

The bottom surface 30B of the TSV structure 30 protrudes from a bottom surface RC2_B of the second recess space RC2. In an exemplary embodiment, the bottom surface 30B of the TSV structure 30 is located to be farther from the bottom surface 120B of the substrate 120 than the bottom surface RC2_B of the second recess space RC2.

Referring to FIG. 10P, the second conductive layer 60 is formed on the upper insulating layer 80 and the exposed part of the TSV structure 30.

The second conductive layer 60 is formed conformally on the side wall RC2_S and the bottom surface RC2_B of the second recess space RC2, and an end portion of the conductive plug 32 protruding in the second recess space RC2.

In an exemplary embodiment, the second conductive layer 60 may be formed of Ti, Cu, Ni, Au, NiV, NiP, TiNi, TiW, TaN, Al, Pd, CuCr, or a combination thereof. The second conductive layer 60 may be formed by a PVD process or a CVD process.

Referring to FIG. 10Q, a metal layer 70R filing the second recess space RC2 is formed on the second conductive layer 60 by an electroplating process.

In an exemplary embodiment, the metal layer 70R may be formed of Ni, Cu, Al, or Au, but the present inventive concept is not limited thereto. In an exemplary embodiment, the electroplating process for forming the metal layer 70R may be a direct current (DC) plating process or a pulse plating process.

In FIG. 10Q, the metal layer 70R completely fills the second recess space RC2 having a predetermined thickness on the second conductive layer 60 on the outside of the second recess space RC2.

Referring to FIG. 10R, the metal layer 70R of FIG. 10Q is polished by a CMP process until the upper insulating layer 80 is exposed. In an exemplary embodiment, the upper insulating layer 80 is further polished after being exposed. Through the CMP process, the metal layer 70R on the outer portion of the second recess space RC2 may be removed, and the metal layer 70R in the second recess space RC2 only remains to form the conductive pad 70. In addition, the second conductive layer 60 on the outside of the second recess space RC2 may be removed.

Through the above processes, the integrated circuit device 100A is formed.

In an exemplary embodiment of manufacturing the integrated circuit device 100A, the second recess space RC2 exposing the TSV structure 30 is formed in the upper insulating layer 80 by the partial-dose photolithography process, and after that, the conductive pad 70 filling the second recess space RC2 is formed. Therefore, the conductive pad 70 is in contact with the TSV structure 30 and/or the upper insulating layer 80 through the second conductive layer 60 so that the detachment or delamination of the conductive pad 70 may be prevented. Also, since the upper surface of the conductive pad 70 is located at the same level as the upper surface of the upper insulating layer 80, an underfill member may be attached without generating a void when the integrated circuit device 100A is attached onto another semiconductor chip or on the package substrate. In addition, the upper insulating layer 80 may cancel the compression stress or the tensile stress that may be applied to the substrate 120 by the passivation layer 150, and thus, warpage of the substrate 120 due to the compression or tensile stress may be prevented. Therefore, the integrated circuit device 100A may be reliable.

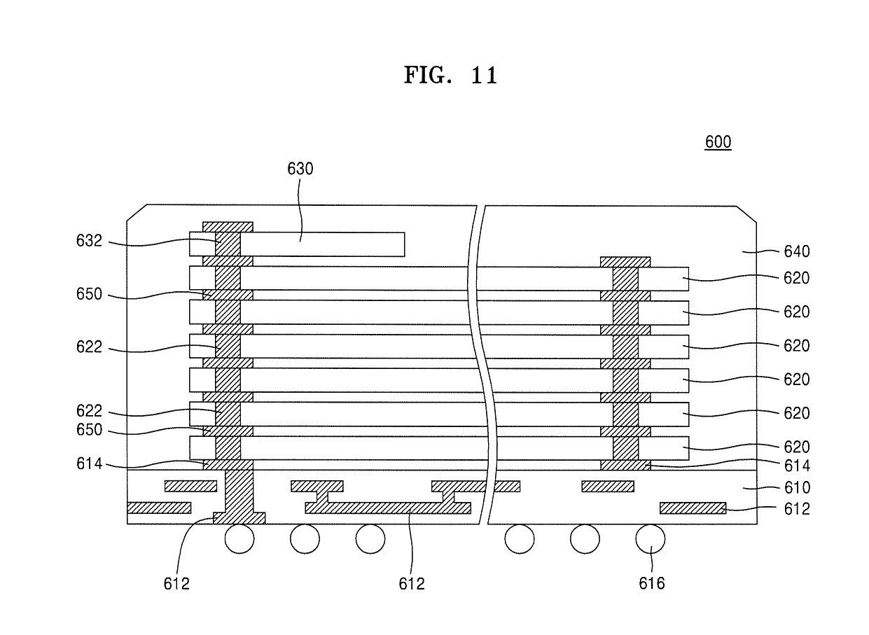

FIG. 11 is a cross-sectional view showing a semiconductor package 600 according to an exemplary embodiment.

Referring to FIG. 11, the semiconductor package 600 includes a plurality of semiconductor chips 620 that are sequentially stacked on a package substrate 610. A control chip 630 is connected onto the plurality of semiconductor chips 620 through a TSV structure. A stack structure of the plurality of semiconductor chips 620 and the control chip 630 is encapsulated by an encapsulant 640 such as a thermosetting resin on the package substrate 610. In FIG. 11, six semiconductor chips 620 are stacked in a vertical direction, but the number and stacked direction of the semiconductor chips 620 are not limited to the above example. The number of the semiconductor chips 620 may be more or less than six in an exemplary embodiment. The plurality of semiconductor chips 620 may be arranged on a horizontal direction on the package substrate 610, or may be arranged in a connecting structure combining the vertical direction mounting and the horizontal direction mounting. In an exemplary embodiment, the control chip 630 may be omitted.

The package substrate 610 may be a flexible printed circuit board, a rigid printed circuit board, or a combination thereof. The package substrate 610 includes internal substrate wires 612 and connection terminals 614. The connection terminals 614 are formed on a surface of the package substrate 610. Solder balls 616 are formed on the other surface of the package substrate 610. The connection terminals 614 are electrically connected to the solder balls 616 via the internal substrate wires 612. In an exemplary embodiment, the solder balls 616 may be replaced by conductive bumps or lead grid arrays (LGAs).

Each semiconductor chip 620 includes a TSV structure 622, and the control chip 630 includes a TSV unit 632. The TSV units 622 and 632 are electrically connected to each other the connection terminal through a connection member 650 such as a bump. The TSV structures 622 and 632 connected to each other is connected to the connection terminal 614. In an exemplary embodiment, the TSV unit 632 of the control chip 630 may be omitted.

At least one of the plurality of semiconductor chips 620 and the control chip 630 may include an integrated circuit device according to an exemplary embodiment. In an exemplary embodiment, a TSV unit may include a TSV structure according to an exemplary embodiment. Each connection member may include a conductive pad as described above with reference to FIGS. 1 to 8 according to an exemplary embodiment. The connection members 650 are connected to the TSV units 622 and 632.

The plurality of semiconductor chips 620 may each include a system large-scale integration (LSI), a flash memory, a dynamic random access memory (DRAM), a static RAM (SRAM), an electrically erasable and programmable read only memory (EEPROM), a parameter RAM (PRAM), a magnetic RAM (MRAM), or a resistance RAM (RRAM). The control chip 630 may include logic circuits such as serializer/deserializer (SER/DES).

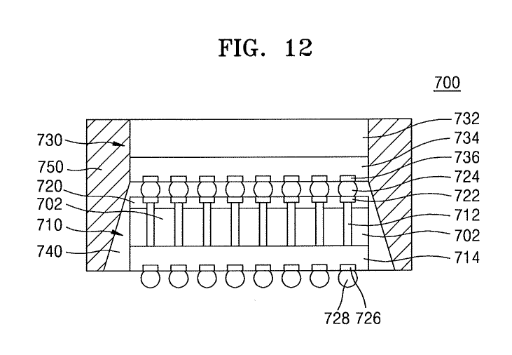

FIG. 12 is a cross-sectional view of a semiconductor package 700 according to an exemplary embodiment.

Referring to FIG. 12, the semiconductor package 700 includes a first chip 710, a second chip 730, an underfill 740, and an encapsulant 750.

The first chip 710 may have an integrated circuit device as described above with reference to FIGS. 1 to 8 according to an exemplary embodiment.

The first chip 710 includes a plurality of TSV units 712 penetrating through a semiconductor structure 702. The plurality of TSV units 712 may each include a TSV structure as described above with reference to FIGS. 1 to 8 according to an exemplary embodiment.

The semiconductor structure 702 may include the semiconductor structure 20 illustrated in FIG. 1 to 5, or the substrate 120 illustrate in FIGS. 6 to 8.

In an exemplary embodiment, the first chip 710 includes the integrated circuit device 100A of FIG. 6, and a device layer 714 of the first chip 710 includes the BEOL structure 140 illustrated in FIG. 6. In an exemplary embodiment, the first chip 710 may include the integrated circuit device 100C of FIG. 8, and the device layer 714 may include the stack structure of the FEOL structure 130 and the BEOL structure 140 illustrated in FIG. 8. In an exemplary embodiment, the first chip 710 may include the integrated circuit device 100B of FIG. 7, and the device layer 714 may be omitted.

An upper insulating layer 720, upper pads 722 connected to end portions of the plurality of the TSV units 712, and connection terminals 724 are disposed at a side of the first chip 710. Also, electrode pads 726 and connection terminals 728 are connected to the other side of the first chip 710. The connection terminals 724 and 728 may include solder balls or bumps.

The upper insulating layer 720 may include an upper insulating layer as described with reference to FIGS. 1 to 8, and the upper pad 722 may include a second conductive layer and a conductive pad connected to the TSV unit 712 via the second conductive layer, as described with reference to FIGS. 1 to 8.

The second chip 730 includes a substrate 732, and a wiring structure 734 formed on the substrate 732. An integrated circuit layer may be further formed on the substrate 732. The second chip 730 need not include a TSV structure. Electrode pads 736 are connected to the wiring structure 734. The wiring structure 734 may be electrically connected to the TSV units 712 via the electrode pads 736, the connection terminals 724, and the upper pads 722.

The underfill 740 fills a connecting portion between the first chip 710 and the second chip 730. For example, the connection terminals 724 of the first chip 710 and the electrode pads 736 of the second chip 730 are connected to each other in the connecting portion. The underfill 740 may be formed of an epoxy resin, and may include silica filler, flux, etc. The underfill 740 may be formed of a material that is the same as or different from the material forming the encapsulant 750 formed on the outside thereof.

The underfill 740 fills the connecting portion between the first chip 710 and the second chip 730 and the side surface of the first chip 710 so that the side surface of the first chip 710 may be encapsulated by the underfill 740.

In FIG. 12, the underfill 740 has a downwardly enlarged shape. However, the shape of the underfill 740 is not limited thereto, and may be variously formed. For example, the underfill 740 need not surround the side surface of the first chip 710, but is formed only in the space between the first chip 710 and the second chip 730.

The encapsulant 750 encapsulates the first chip 710 and the second chip 730. The encapsulant 750 may be formed of polymer, e.g., an epoxy molding compound (EMC). The encapsulant 750 encapsulates side surfaces of the second chip 730 and the underfill 740. In an exemplary embodiment, when the underfill 740 is formed only in the space between the first chip 710 and the second chip 730, the encapsulant 750 encapsulates the side surface of the first chip 710.

An upper surface of the second chip 730 need not be encapsulated by the encapsulant 750, but may be exposed to the outside.

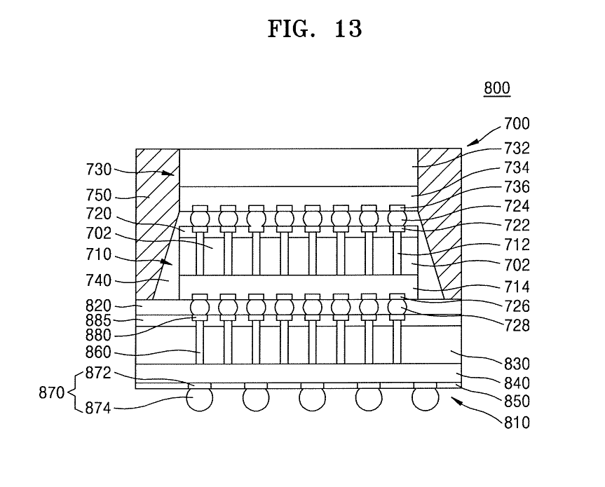

FIG. 13 is a cross-sectional view of a semiconductor package 800 according to an exemplary embodiment. In FIG. 13, the like reference numerals as those of FIG. 12 denote the same elements, and detailed descriptions thereof are omitted here.

Referring to FIG. 13, the semiconductor package 800 includes a semiconductor chip 810 and the semiconductor package 700 of FIG. 12 mounted on the semiconductor chip 810.

The semiconductor package 700 is described above in detail with reference to FIG. 12.

The semiconductor chip 810 may have a horizontal cross-section, an area of which is greater than those of the first chip 710 and the second chip 730 included in the semiconductor package 700. In an exemplary embodiment, the area of the horizontal cross-section of the main chip 810 may be substantially equal to that of the horizontal cross-section of the semiconductor package 700 including the encapsulant 750. The semiconductor package 700 may be mounted on the semiconductor chip 810 via an adhesive member 820. In addition, bottom surfaces of the encapsulant 750 and the underfill 740 of the semiconductor package 700 are respectively attached to an upper outer portion of the main chip 810 via the adhesive member 820.

The semiconductor chip 810 includes a body layer 830, a lower insulating layer 840, a passivation layer 850, a plurality of TSV units 860 penetrating through the body layer 830, a plurality of connection terminals 870, upper pads 880, and an upper insulating layer 885.

The plurality of TSV units 860 may each include a TSV structure as illustrated with reference to FIGS. 1 to 8.

An integrated circuit layer and multi-layered wiring patterns may be respectively included in the body layer 830 and the lower insulating layer 840. The integrated circuit layer and the multi-layered wiring patterns may vary depending on a kind of the semiconductor chip 810. The semiconductor chip 810 may form a logic chip, e.g., a central processing unit (CPU), a controller, or an application specific integrated circuit (ASIC).

In FIG. 13, the semiconductor package 700 is stacked on the semiconductor chip 810, but the semiconductor package 700 may be directly mounted on a support substrate such as a printed circuit board (PCB), or a package substrate.

Each of the plurality of connection terminals 870 formed under the semiconductor chip 810 includes a pad 872 and a solder ball 874. The connection terminals 870 formed under the semiconductor chip 810 may be greater than the connection terminals 728 formed in the semiconductor package 700.

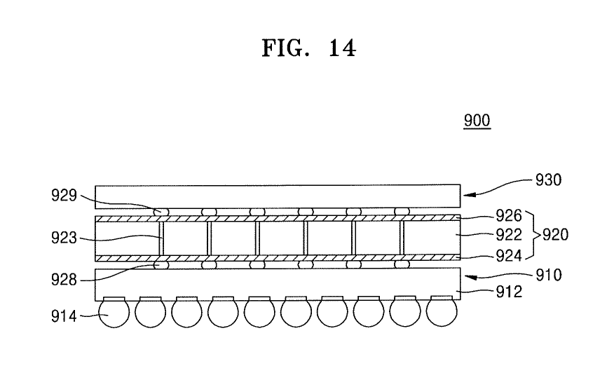

FIG. 14 is a cross-sectional view of a semiconductor package 900 according to an exemplary embodiment. In FIG. 14, the semiconductor package 900 is a package on package (POP), in which a lower semiconductor package 910 and an upper semiconductor package 930 are flip-chip bonded to an interposer 920 having a TSV structure.

Referring to FIG. 14, the semiconductor package 900 includes the lower semiconductor package 910, the interposer 920 including a plurality of TSV units 923 therein, and the upper semiconductor package 930.

The plurality of TSV units 923 may each include a TSV structure as described above with reference to FIGS. 1 to 8 according to an exemplary embodiment.

A plurality of first connection terminals 914 are attached to a lower portion of a substrate 912 in the lower semiconductor package 910. The plurality of first connection terminals 914 may be used to connect the semiconductor package 900 to a PCB of an electronic device. In an exemplary embodiment, the plurality of first connection terminals 914 may each include a solder ball or a solder land.

The interposer 920 is used to form a vertical connection terminal for connecting the lower semiconductor package 910 and the upper semiconductor package 930 to each other in a fine pitch. By using the interposer 920, a plane area of the POP integrated circuit device may be reduced. The interposer 920 includes a silicon layer 922, through which the plurality of TSV units 923 penetrate, and redistribution layers 924 and 926 formed on a bottom surface and an upper surface of the silicon layer 922 to redistribute the plurality of TSV units 923.

In an exemplary embodiment, at least one of the redistribution layers 924 and 926 may include a second conductive layer as described with reference to FIGS. 1 to 8, and the conductive pad 70, 70A, 70B, or 70C connected to the TSV units 923 via the second conductive layer 60.

In an exemplary embodiment, at least one of the redistribution layers 924 and 926 may be omitted.

A plurality of second connection terminals 928 for connecting the plurality of TSV units 923 to the substrate 912 of the lower semiconductor package 910 are formed on the bottom surface of the interposer 920. A plurality of third connection terminals 929 for connecting the plurality of TSV units 923 to the upper semiconductor package 930 are formed on the upper surface of the interposer 920. In an exemplary embodiment, the second connection terminals 928 and the third connection terminals 929 may each include a solder bump or a solder land.

If the semiconductor package 900 is a semiconductor device used in a mobile phone, the lower semiconductor package 910 may be a logic device such as a processor and the upper semiconductor package 930 may be a memory device.

In an exemplary embodiment, the upper semiconductor package 930 may be a multi-chip package, in which a plurality of semiconductor chips (not shown) are stacked, and an upper portion of the upper semiconductor package 930 may be encapsulated by an encapsulant (not shown) for protecting the semiconductor chips.

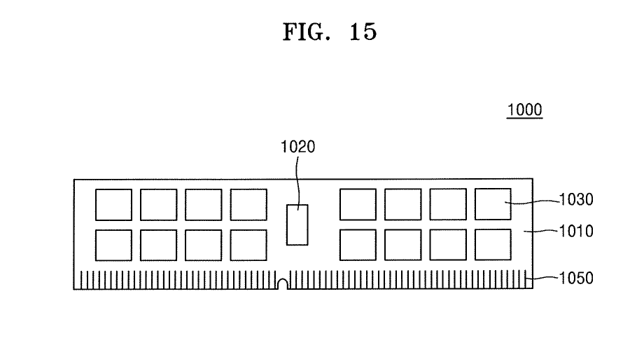

FIG. 15 is a plan view showing an integrated circuit device 1000 according to an exemplary embodiment.

The integrated circuit device 1000 includes a module substrate 1010, a buffer chip 1020 mounted on the module substrate 1010, and a plurality of semiconductor packages 1030. A plurality of input/output terminals 1150 are formed on the module substrate 1010.

The plurality of semiconductor packages 1030 may include an integrated circuit device as described with reference to FIGS. 1 to 8 according to an exemplary embodiment.

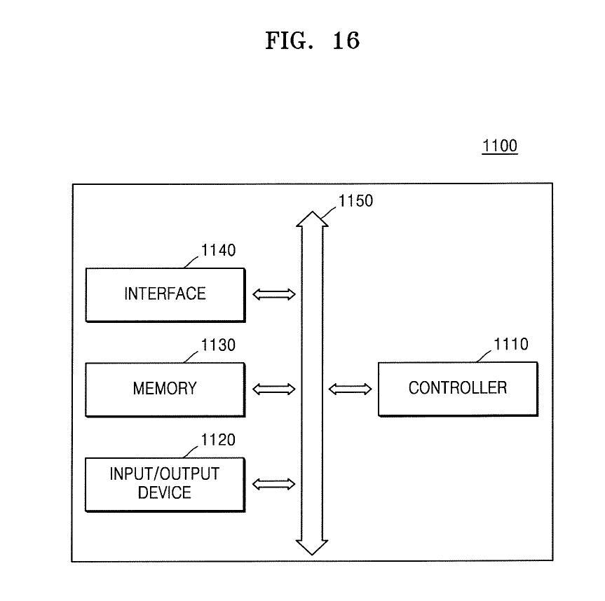

FIG. 16 is a diagram illustrating an integrated circuit device 1100 according to an exemplary embodiment.

The integrated circuit device 1100 includes a controller 1110, an input/output device 1120, a memory 1130, and an interface 1140. The integrated circuit device 1100 may be a mobile system or a system for transmitting or receiving information. In an exemplary embodiment, the mobile system may be a personal digital assistant (PDA), a portable computer, a Web tablet, a wireless phone, a mobile phone, a digital music player, or a memory card.

In an exemplary embodiment, the controller 1110 may be a microprocessor, a digital signal processor, or a micro-controller.

The input/output device 1120 is used to input and output data of the integrated circuit device 1100. The integrated circuit device 1100 may be connected to an external device, for example, a personal computer or a network, via the input/output device 1120, and may exchange data with the external device. In an exemplary embodiment, the input/output device 1120 may be a keypad, a keyboard, or a display.

In an exemplary embodiment, the memory 1130 stores codes and/or data for operating the controller 1110. In an exemplary embodiment, the memory 1130 stores data processed by the controller 1110. At least one of the controller 1110 and the memory 1130 includes a integrated circuit device as described above with reference to FIGS. 1 to 8.

The interface 1140 may function as a data transmission path between the integrated circuit device 1100 and another external device. The controller 1110, the input/output device 1120, the memory 1130, and the interface 1140 may communicate with each other via a bus 1150.

The integrated circuit device 1100 may be included in a mobile phone, an MP3 player, a navigation system, a portable multimedia player (PMP), a solid state disk (SSD), or household appliances.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

1. An integrated circuit device comprising:
a semiconductor structure;
a connection terminal disposed on a first surface of the semiconductor structure;
a conductive pad disposed on a second surface, opposite to the first surface, of the semiconductor structure;
a through-substrate-via (TSV) structure penetrating through the semiconductor structure, wherein an end portion of the TSV structure extends beyond the second surface of the semiconductor structure,
wherein the conductive pad surrounds the end portion of the TSV structure, and
wherein the connection terminal is electrically connected to the conductive pad through the TSV structure.

2. The integrated circuit device of claim 1, further comprising:
an insulating layer disposed on the second surface of the semiconductor structure,
wherein the insulating layer comprises:
a first portion surrounding a side wall of the conductive pad; and
a second portion overlapping vertically the conductive pad and surrounding a part of a side wall of the TSV structure, wherein the part of the side wall is disposed between the conductive pad and the second surface of the semiconductor structure.

3. The integrated circuit device of claim 2,
wherein the first portion and the second portion of the insulating layer are in contact with each other.

4. The integrated circuit device of claim 2,
wherein an upper surface of the first portion of the insulating layer is located at a same level as the upper surface of the conductive pad.

5. The integrated circuit device of claim 2,
wherein the insulating layer comprises a recess space exposing the end portion of the TSV structure, and the conductive pad fills in the recess space.

6. The integrated circuit device of claim 2, further comprising:
a conductive layer disposed between the insulating layer and the conductive pad,
wherein the conductive layer contacts the side wall of the conductive pad.

7. The integrated circuit device of claim 6,
wherein the conductive layer disposed between the TSV structure and the conductive pad, the conductive layer conformally covering the end portion of the TSV structure.

8. The integrated circuit device of claim 1,
wherein the end portion of the TSV structure has a rounded shape.

9. The integrated circuit device of claim 2,
wherein the insulating layer comprises a photosensitive organic insulating material.

10. The integrated circuit device of claim 1,
wherein the side wall of the conductive pad is inclined at a predetermined angle.

11. The integrated circuit device of claim 1,
wherein the conductive pad has a decreasing width toward the end of the TSV structure.

12. The integrated circuit device of claim 1,
wherein the conductive pad comprises a stepped portion on the side wall.

13. The integrated circuit device of claim 2, further comprising:
an adhesion layer disposed between the semiconductor structure and the insulating layer and between the TSV structure and the insulating layer.

14. The integrated circuit device of claim 13,
wherein the adhesion layer surrounds a side wall of the TSV structure, and
wherein the side wall of the TSV structure is disposed between the conductive pad and the semiconductor structure.

15.-17. (canceled)

18. An integrated circuit device comprising:
a semiconductor structure;
a through-substrate-via (TSV) structure penetrating through the semiconductor structure;
an insulating layer disposed on the semiconductor structure and comprising a recess space exposing an end portion of the TSV structure; and
a conductive pad filling in the recess space and connected to the end portion of the TSV structure.

19. The integrated circuit device of claim 18,
wherein the insulating layer comprises a first portion that does not vertically overlap with the conductive pad and a second portion that vertically overlaps with the conductive pad, and the second portion of the insulating layer surrounds a side wall of the TSV structure between the semiconductor structure and the conductive pad.

20.-33. (canceled)

34. A semiconductor device, comprising:
a first integrated circuit device having a first electrical connection structure and a connection terminal which is electrically connected to the first electrical connection structure;
a second integrated circuit device vertically stacked on the first integrated circuit device;
wherein the connection terminal electrically connects the first electrical connection structure to the second integrated circuit device, and
wherein the first integrated circuit device further comprises:
a first semiconductor structure having a first surface and a second surface opposite to the first surface; and
a conductive pad disposed on The second surface, opposite to the first surface, of the first semiconductor structure,
wherein the connection terminal is disposed on the first surface of the first semiconductor structure,
wherein the first electrical connection structure penetrates through the first semiconductor structure, wherein an end portion of the first electrical connection structure extends beyond the second surface of the first semiconductor structure,
wherein the conductive pad surrounds the end portion of the first electrical connection structure, and
wherein the connection terminal is electrically connected to the conductive pad through the first electrical connection structure.

35. The semiconductor device of claim 34, wherein the first integrated circuit device further comprises an insulation layer formed of a photosensitive organic insulating material, and wherein the insulation layer includes an recess space exposing the end portion of the first electrical connection structure.

36. The semiconductor device of claim 35, wherein the second integrated circuit device includes a second semiconductor structure and a second electrical connection structure penetrating the second semiconductor structure, and wherein the second electrical connection structure is electrically connected to the first electrical connection structure.

37. The semiconductor device of claim 34,
wherein the first electrical connection structure comprises:
a conductive barrier layer disposed on a side wall of a via hole that penetrates through the first semiconductor structure; and
a conductive plug filling in the via hole on the conductive barrier layer, and
wherein the first integrated circuit device further comprises a conductive layer including a first part disposed between the conductive plug and the conductive pad in the recess space.
